(19) United States
(12) Patent Application Publication
(10) Pub. No.: US 2019/0198622 A1
(43) Pub. Date: Jun. 27, 2019

(54) SILICON CARBIDE SEMICONDUCTOR DEVICE AND METHOD FOR MANUFACTURING SAME

(71) Applicant: Sumitomo Electric Industries, Ltd., Osaka-shi (JP)

(72) Inventors: Kosuke UCHIDA, Osaka-shi, Osaka (JP); Toru HIYOSHI, Osaka-shi (JP); Mitsuhiko SAKAI, Osaka-shi (JP)

(21) Appl. No.: 16/329,679

(22) PCT Filed: Jun. 20, 2017
(86) PCT No.: PCT/JP2017/022651

§ 371 Date: Feb. 28, 2019

(30) Foreign Application Priority Data
Aug. 31, 2016 (JP) 2016-169624

(51) Int. Cl. H01L 29/16; H01L 29/417; H01L 29/78; H01L 29/66

(52) U.S. Cl. CPC H01L 29/1608; H01L 29/41741; H01L 29/66068; H01L 29/66727; H01L 29/66734; H01L 29/7813

(57) ABSTRACT

A first main surface is provided with: a gate trench defined by a first side surface and a first bottom surface; and a source trench defined by a second side surface and a second bottom surface. A silicon carbide substrate includes a drift region, a body region, a source region, a first region, and a second region. The first region is in contact with the second region. A gate insulating film is in contact with the drift region, the body region, and the source region at the first side surface, and is in contact with the drift region at the first bottom surface. A source electrode is in contact with the second region at the second side surface and the second bottom surface.

### TECHNICAL FIELD

The present disclosure relates to a silicon carbide semiconductor device and a method for manufacturing the silicon carbide semiconductor device. The present application claims a priority based on Japanese Patent Application No. 2016-169624 filed on Aug. 31, 2016, the entire content of which is incorporated herein by reference.

### BACKGROUND ART

WO 2012/017798 (Patent Literature 1) discloses a MOSFET (Metal Oxide Semiconductor Field Effect Transistor) provided with a gate trench in a surface of a breakdown voltage holding layer.

### CITATION LIST

### Patent Literature

PTL 1: WO 2012/017798

### SUMMARY OF INVENTION

A silicon carbide semiconductor device according to one embodiment of the present disclosure includes a silicon carbide substrate, a gate insulating film, and a source electrode. The silicon carbide substrate has a first main surface and a second main surface opposite to the first main surface. A gate trench and a source trench are provided in the first main surface. The gate trench is defined by a first side surface continuous to the first main surface and a first bottom surface continuous to the first side surface. The source trench is defined by a second side surface continuous to the first main surface and a second bottom surface continuous to the second side surface. The silicon carbide substrate includes: a drift region having a first conductivity type; a body region provided on the drift region and having a second conductivity type different from the first conductivity type; a source region on the body region, the source region being separated from the drift region by the body region, the source region having the first conductivity type; a first region between the second bottom surface and the second main surface, the first region having the second conductivity type; and a second region in contact with the first region, the second region constituting at least a portion of the second side surface and the second bottom surface, the second region having the second conductivity type. The gate insulating film is in contact with the drift region, the body region, and the source region at the first side surface, and the gate insulating film is in contact with the drill region at the first bottom surface. The source electrode is in contact with the second region at the second side surface and the second bottom surface.

A silicon carbide semiconductor device according to one embodiment of the present disclosure includes a silicon carbide substrate, a gate insulating film, and a source electrode. The silicon carbide substrate has a first main surface and a second main surface opposite to the first main surface. The first main surface corresponds to a {0001} plane or a plane angled off by less than or equal to 8° relative to the {0001} plane. A gate trench and a source trench are provided in the first main surface. The gate trench is defined by a first side surface continuous to the first main surface and a first bottom surface continuous to the first side surface. An angle of the first side surface relative to the first bottom surface is more than or equal to 50° and less than or equal to 65°. The source trench is defined by a second side surface continuous to the first main surface and a second bottom surface continuous to the second side surface. An angle of the second side surface relative to the second bottom surface is more than or equal to 50° and less than or equal to 65°. The silicon carbide substrate includes: a drift region having a first conductivity type; a body region provided on the drift region and having a second conductivity type different from the first conductivity type; a source region on the body region, the source region being separated from the drift region by the body region, the source region having the first conductivity type; a first region between the second bottom surface and the second main surface, the first region having the second conductivity type; and a second region in contact with the first region, the second region constituting at least a portion of the second side surface and the second bottom surface, the second region having the second conductivity type. The gate insulating film is in contact with the drift region, the body region, and the source region at the first side surface, and the gate insulating film is in contact with the drift region at the first bottom surface. The source electrode is in contact with the second region at the second side surface and the second bottom surface. The second region has a third region and a fourth region, the third region being in contact with the first region, the fourth region being continuous to the third region, the fourth region being in contact with the drift region. A concentration of a second conductivity type impurity in the second bottom surface is higher than a concentration of the second conductivity type impurity in a boundary between the third region and the fourth region.

A method for manufacturing a silicon carbide semiconductor device according to one embodiment of the present disclosure includes the following steps. A silicon carbide substrate having a first main surface and a second main surface opposite to the first main surface is prepared. A gate trench and a source trench are formed in the first main surface. The gate trench is defined by a first side surface continuous to the first main surface and a first bottom surface continuous to the first side surface. The source trench is defined by a second side surface continuous to the first main surface and a second bottom surface continuous to the second side surface. The silicon carbide substrate includes: a drift region having a first conductivity type; a body region provided on the drift region and having a second conductivity type different from the first conductivity type; a source region on the body region, the source region being separated from the drift region by the body region, the source region having the first conductivity type; and a first region between the second bottom surface and the second main surface, the first region having the second conductivity type. A second region is formed by performing ion implantation to the second side surface and the second bottom surface, the second region being in contact with the first region, the second region constituting at least a portion of the second side surface and the second bottom surface, the second region having the second conductivity type. A gate insulating film is formed, the gate insulating film being in contact with the drift region, the body region, and the source region at the first side surface, the gate insulating film being in contact with the drift region at the first bottom surface. A source electrode is formed. in contact with the second region at the second side surface and the second bottom surface.

A method for manufacturing a silicon carbide semiconductor device according to one embodiment of the present disclosure includes the following steps. A silicon carbide substrate having a first main surface and a second main surface opposite to the first main surface is prepared. A gate trench and a source trench are formed simultaneously in the first main surface by thermal etching. The gate trench is defined by a first side surface continuous to the first main surface and a first bottom surface continuous to the first side surface. The source trench is defined by a second side surface continuous to the first main surface and a second bottom surface continuous to the second side surface. The silicon carbide substrate includes: a drift region having a first conductivity type; a body region provided on the drift region and having a second conductivity type different from the first conductivity type; a source region on the body region, the source region being separated from the drift region by the body region, the source region having the first conductivity type; and a first region between the second bottom surface and the second main surface, the first region having the second conductivity type. A second region is formed by performing ion implantation to the second side surface and the second bottom surface, the second region being in contact with the first region, the second region constituting at least a portion of the second side surface and the second bottom surface, the second region having the second conductivity type. Activation annealing is performed to the silicon carbide substrate after the forming of the second region. A gate insulating film is formed after the performing of the activation annealing to the silicon carbide substrate, the gate insulating film being in contact with the drift region, the body region, and the source region at the first side surface, the gate insulating film being in contact with the drift region at the first bottom surface. A source electrode is formed in contact with the second region at the second side surface and the second bottom surface. The forming of the second region includes: performing ion implantation on a condition of first energy and a first dose amount; and performing ion implantation on a condition of second energy and a second dose amount, the second energy being higher than the first energy, the second dose amount being lower than the first dose amount.

### BRIEF DESCRIPTION OF DRAWINGS

FIG. 1 is a schematic cross sectional view showing a configuration of a silicon carbide semiconductor device according to the present embodiment.

FIG. 2 shows a p type impurity concentration distribution in a direction along an arrow II of FIG. 1.

FIG. 3 is a schematic plan view showing a configuration of a silicon carbide substrate of the silicon carbide semiconductor device according to the present embodiment.

FIG. 4 shows a first modification of the p type impurity concentration distribution of a first region 1 and a second region 2 in the direction along arrow II of FIG. 1.

FIG. 5 shows a second modification of the p type impurity concentration distribution of first region 1 and second region 2 in the direction along arrow II of FIG. 1.

FIG. 6 is a schematic plan view showing a configuration of a silicon carbide substrate of a third modification of the silicon carbide semiconductor device according to the present embodiment.

FIG. 7 is a schematic cross sectional view showing a configuration of a fourth modification of the silicon carbide semiconductor device according to the present embodiment.

FIG. 8 shows a p type impurity concentration distribution in a direction along an arrow VIII of FIG. 7.

FIG. 9 is a schematic cross sectional view showing a configuration of a silicon carbide substrate of a fifth modification of the silicon carbide semiconductor device according to the present embodiment.

FIG. 10 is a flowchart schematically showing a method for manufacturing the silicon carbide semiconductor device according to the present embodiment.

FIG. 11 is a schematic cross sectional view showing a first step of the method for manufacturing the silicon carbide semiconductor device according to the present embodiment.

FIG. 12 is a schematic cross sectional view showing a second step of the method for manufacturing the silicon carbide semiconductor device according to the present embodiment.

FIG. 13 is a schematic cross sectional view showing a third step of the method for manufacturing the silicon carbide semiconductor device according to the present embodiment.

FIG. 14 is a schematic cross sectional view showing a fourth step of the method for manufacturing the silicon carbide semiconductor device according to the present embodiment.

FIG. 15 is a schematic cross sectional view showing a fifth step of the method for manufacturing the silicon carbide semiconductor device according to the present embodiment.

FIG. 16 is a schematic cross sectional view showing a sixth step of the method for manufacturing the silicon carbide semiconductor device according to the present embodiment.

FIG. 17 is a schematic cross sectional view showing a seventh step of the method for manufacturing the silicon carbide semiconductor device according to the present embodiment.

FIG. 18 is a schematic cross sectional view showing an eighth step of the method for manufacturing the silicon carbide semiconductor device according to the present embodiment.

FIG. 19 is a flowchart schematically showing a first modification of the method for manufacturing the silicon carbide semiconductor device according to the present embodiment.

FIG. 20 is a schematic cross sectional view showing a step of forming a source trench in the first modification of the method for manufacturing the silicon carbide semiconductor device according to the present embodiment.

FIG. 21 is a schematic cross sectional view showing a step of forming a second region in the first modification of the method for manufacturing the silicon carbide semiconductor device according to the present embodiment.

FIG. 22 is a schematic cross sectional view showing a step of forming a gate trench in the first modification of the method for manufacturing the silicon carbide semiconductor device according to the present embodiment.

FIG. 23 is a schematic cross sectional view showing a first step of a step of forming a second region in a second modification of the method for manufacturing the silicon carbide semiconductor device according to the present embodiment.

FIG. 24 is a schematic cross sectional view showing a second step of the step of forming the second region in the second modification of the method for manufacturing the silicon carbide semiconductor device according to the present embodiment.

FIG. 25 is a schematic cross sectional view showing a configuration of a silicon carbide substrate of a sixth modification of the silicon carbide semiconductor device according to the present embodiment.

FIG. 26 is a schematic cross sectional view showing a configuration of a silicon carbide substrate of a seventh modification of the silicon carbide semiconductor device according to the present embodiment.

FIG. 27 is a schematic cross sectional view showing a configuration of a silicon carbide substrate of an eighth modification of the silicon carbide semiconductor device according to the present embodiment.

FIG. 28 is a schematic cross sectional view showing a configuration of a silicon carbide substrate of a ninth modification of the silicon carbide semiconductor device according to the present embodiment.

FIG. 29 is a schematic cross sectional view showing a configuration of a silicon carbide substrate of a tenth modification of the silicon carbide semiconductor device according to the present embodiment.

FIG. 30 is a schematic cross sectional view showing a configuration of a silicon carbide substrate of an eleventh modification of the silicon carbide semiconductor device according to the present embodiment.

FIG. 31 is a schematic cross sectional view showing a configuration of a silicon carbide substrate of a twelfth modification of the silicon carbide semiconductor device according to the present embodiment.

FIG. 32 is a schematic cross sectional view showing a configuration of a silicon carbide substrate of a thirteenth modification of the silicon carbide semiconductor device according to the present embodiment.

FIG. 33 is a schematic cross sectional view showing a configuration of a silicon carbide substrate of a fourteenth modification of the silicon carbide semiconductor device according to the present embodiment.

### DETAILED DESCRIPTION

### [Problems to be Solved by the Present Disclosure]

An object of the present disclosure is to provide a silicon carbide semiconductor device and a method for manufacturing the silicon carbide semiconductor device, by each of which contact resistance can be reduced while suppressing increase of reverse transfer capacitance that affects a switching characteristic.

### [Advantageous Effect of the Present Disclosure]

According to the present disclosure, there can be provided a silicon carbide semiconductor device and a method for manufacturing the silicon carbide semiconductor device, by each of which contact resistance can be reduced while suppressing increase of reverse transfer capacitance that affects a switching characteristic.

### [Description of Embodiments]

(1) A silicon carbide semiconductor device 100 according to one embodiment of the present disclosure includes a silicon carbide substrate, a gate insulating film 15, and a source electrode 16. Silicon carbide substrate 10 has a first main surface 51 and a second main surface 52 opposite to first main surface 51. A gate trench 30 and a source trench 40 are provided in first main surface 51. Gate trench 30 is defined by a first side surface 31 continuous to first main surface 51 and a first bottom surface 32 continuous to first side surface 31. Source trench 40 is defined by a second side surface 41 continuous to first main surface 51 and a second bottom surface 42 continuous to second side surface 41. Silicon carbide substrate 10 includes: a drift region 12 having a first conductivity type; a body region 13 provided on drift region 12 and having a second conductivity type different from the first conductivity type; a source region 14 on body region 13, source region 14 being separated from drift region 12 by body region 13, source region 14 having the first conductivity type; a first region 1 between second bottom surface 42 and second main surface 52, first region 1 having the second conductivity type; and a second region 2 in contact with first region 1, second region 2 constituting at least a portion of second side surface 41 and second bottom surface 42, second region 2 having the second conductivity type. Gate insulating film 15 is in contact with drift region 12, body region 13, and source region 14 at first side surface 31, and gate insulating film 15 is in contact with drift region 12 at first bottom surface 32. Source electrode 16 is in contact with second region 2 at second side surface 41 and second bottom surface 42.

According to silicon carbide semiconductor device 100 according to (1), source electrode 16 is in contact with second region 2 at second side surface 41 and second bottom surface 42. Hence, a contact area between source electrode 16 and second region 2 can be increased as compared with a case where source electrode 16 is in contact with second region 2 only at first main surface 51. As a result, contact resistance between source electrode 16 and second region 2 can be reduced. Moreover, second region 2 is in contact with source electrode 16 while extending via first region 1. Accordingly, second region 2 and source electrode 16 can have the same potential. As a result, reverse transfer capacitance of the silicon carbide semiconductor device can be suppressed from being increased. Further, second region 2 serves to suppress an electric field from being concentrated at a corner portion between first side surface 31 and first bottom surface 32 of gate trench 30. As a result, damage to gate insulating film 15 can be reduced.

(2) In silicon carbide semiconductor device 100 according to (1), second region 2 may constitute a portion of first main surface 51. Source electrode 16 may be in contact with second region 2 at first main surface 51.

(3) in silicon carbide semiconductor device 100 according to (2), second region 2 may have a third region 3 and a fourth region 4, third region 3 being in contact with first region 1, fourth region 4 being continuous to third region 3, fourth region 4 being in contact with drift region 12. A concentration of a second conductivity type impurity in second bottom surface 42 may be higher than a concentration of the second conductivity type impurity in a boundary 17 between third region 3 and fourth region 4.

(4) In silicon carbide semiconductor device 100 according to (2) or (3), an angle θ1 of first side surface 31 relative to first bottom surface 32 may be more than or equal to 50° and less than or equal to 65°. Accordingly, mobility of a channel formed in body region 13 can be improved.

(5) In silicon carbide semiconductor device 100 according to any one of (2) to (4), an angle θ2 of second side surface 41 relative to second bottom surface 42 may be more than or equal to 50° and less than or equal to 65°. Accordingly, contact resistance between source electrode 16 and second region 2 can be reduced without excessively reducing a cell density.

(6) In silicon carbide semiconductor device 100 according to any one of (2) to (4), an angle θ2 of the second side surface relative to the second bottom surface may be more than 65° and less than or equal to 90°.

(7) In silicon carbide semiconductor device 100 according to (6), in a direction perpendicular to second main surface 52, second bottom surface 42 may be located between source region 14 and drift region 12.

(8) in silicon carbide semiconductor device 100 according to (6), in a direction perpendicular to second main surface 52, second bottom surface 42 may be located between body region 13 and first region 1.

(9) In silicon carbide semiconductor device 100 according to any one of (2) to (8), silicon carbide substrate 10 may further include an impurity region 18, impurity region 18 having the first conductivity type, impurity region 18 being located between first bottom surface 32 and second main surface 52, impurity region 18 facing first region 1. A concentration of a first conductivity type impurity in impurity region 18 may be higher than a concentration of the first conductivity type impurity in drift region 12.

(10) In silicon carbide semiconductor device 100 according to any one of (2) to (4) and (9), second side surface 41 may have a first side portion 43 continuous to second bottom surface 42, and a second side portion 44 continuous to first side portion 43. An angle θ2 of first side portion 43 relative to second bottom surface 42 may be smaller than an angle θ3 of second side portion 44 relative to a plane parallel to second bottom surface 42.

(11) In silicon carbide semiconductor device 100 according to (1), source electrode 16 may be in contact with source region 14 at second side surface 41, Second region 2 may be separated from first main surface 51.

(12) In silicon carbide semiconductor device 100 according to (11), second region 2 may have a third region 3 and a fourth region 4, third region 3 being in contact with first region 1, fourth region 4 being continuous to third region 3, fourth region 4 being in contact with drift region 12. A concentration of a second conductivity type impurity in second bottom surface 42 may be higher than a concentration of the second conductivity type impurity in a boundary 17 between third region 3 and fourth region 4.

(13) In silicon carbide semiconductor device 100 according to (11) or (12), an angle θ1 of first side surface 31 relative to first bottom surface 32 may be more than or equal to 50° and less than or equal to 65°. Accordingly, mobility of a channel formed in body region 13 can be improved.

(14) In silicon carbide semiconductor device 100 according to any one of (11) to (13), an angle θ2 of second side surface 41 relative to second bottom surface 42 may be more than or equal to 50° and less than or equal to 65°. Accordingly, contact resistance between source electrode 16 and second region 2 can be reduced without excessively reducing a cell density.

(15) In silicon carbide semiconductor device 100 according to any one of (11) to (13), an angle θ2 of the second side surface relative to the second bottom surface may be more than 65′ and less than or equal to 90°.

(16) In silicon carbide semiconductor device 100 according to (15), in a direction perpendicular to second main surface 52, second bottom surface 42 may be located between source region 14 and drift region 12.

(17) In silicon carbide semiconductor device 100 according to (15), in a direction perpendicular to second main surface 52, second bottom surface 42 may be located between body region 13 and first region 1.

(18) In silicon carbide semiconductor device 100 according to any one of (11) to (17), silicon carbide substrate 10 may further include an impurity region 18, impurity region 18 having the first conductivity type, impurity region 18 being located between first bottom surface 32 and second main surface 52, impurity region 18 facing first region 1. A concentration of a first conductivity type impurity in impurity region 18 may be higher than a concentration of the first conductivity type impurity in drift region 12.

(19) In silicon carbide semiconductor device 100 according to any one of (11) to (13) and (18), second side surface 41 may have a first side portion 43 continuous to second bottom surface 42, and a second side portion 44 continuous to first side portion 43. An angle θ2 of first side portion 43 relative to second bottom surface 42 may be smaller than an angle θ3 of second side portion 44 relative to a plane parallel to second bottom surface 42.

(20) In silicon carbide semiconductor device 100 according to any one of (1) to (19), first main surface 51 may correspond to a {0001} plane or a plane angled off by less than or equal to 8° relative to the {0001} plane.

(21) A silicon carbide semiconductor device 100 according to one embodiment of the present disclosure includes a silicon carbide substrate 10, a gate insulating film 15, and a source electrode 16. Silicon carbide substrate 10 has a first main surface 51 and a second main surface 52 opposite to first main surface 51. First main surface 51 corresponds to a {0001} plane or a plane angled off by less than or equal to 8° relative to the {0001} plane. A gate trench 30 and a source trench 40 are provided in first main surface 51. Gate trench 30 is defined by a first side surface 31 continuous to first main surface 51 and a first bottom surface 32 continuous to first side surface 31. An angle θ1 of first side surface 31 relative to first bottom surface 32 is more than or equal to 50° and less than or equal to 65°. Source trench 40 is defined by a second side surface 41 continuous to first main surface 51 and a second bottom surface 42 continuous to second side surface 41. An angle θ2 of second side surface 41 relative to second. bottom surface 42 is more than or equal to 50° and less than or equal to 65°. Silicon carbide substrate 10 includes: a drift region 12 having a first conductivity type; a body region 13 provided on drift region 12 and having a second conductivity type different from the first conductivity type; a source region 14 on body region 13, source region 14 being separated from drift region 12 by body region 13, source region 14 having the first conductivity type; a first region 1 between second bottom surface 42 and second main surface 52, first region 1 having the second conductivity type; and a second region 2 in contact with first region 1, second region 2 constituting at least a portion of second side surface 41 and second bottom surface 42, second region 2 having the second conductivity type. Gate insulating film 15 is in contact with drift region 12, body region 13, and source region 14 at first side surface 31, and gate insulating film 15 is in contact with drift region 12 at first bottom surface 32. Source electrode 16 is in contact with second region 2 at second side surface 41 and second bottom surface 42. Second region 2 has a third region 3 and a fourth region 4, third region 3 being in contact with first region 1, fourth region 4 being continuous to third region 3, fourth region 4 being in contact with drift region 12. A concentration of a second conductivity type impurity in second bottom surface 42 is higher than a concentration of the second conductivity type impurity in a boundary 17 between third region 3 and fourth region 4.

(22) A method for manufacturing a silicon carbide semiconductor device 100 according to one embodiment of the present disclosure includes the following steps. A silicon carbide substrate 10 having a first main surface 51 and a second main surface 52 opposite to first main surface 51 is prepared. A gate trench 30 and a source trench 40 are formed in first main surface 51. Gate trench 30 is defined by a first side surface 31 continuous to first main surface 51 and a first bottom surface 32 continuous to first side surface 31. Source trench 40 is defined by a second side surface 41 continuous to first main surface 51 and a second bottom surface 42 continuous to second side surface 41. Silicon carbide substrate 10 includes: a drift region 12 having a first conductivity type; a body region 13 provided on drift region 12 and having a second conductivity type different from the first conductivity type; a source region 14 on body region 13, source region 14 being separated from drift region 12 by body region 13, source region 14 having the first conductivity type; and a first region 1 between second bottom surface 42 and second main surface 52, first region 1 having the second conductivity type. A second region 2 is formed by performing ion implantation to second side surface 41 and second bottom surface 42, second region 2 being in contact with first region 1, second region 2 constituting at least a portion of second side surface 41. and second bottom surface 42, second region 2 having the second conductivity type. A gate insulating film 15 is formed, gate insulating film 15 being in contact with drift region 12, body region 13, and source region 14 at first side surface 31, gate insulating film 15 being in contact with drift region 12 at first bottom surface 32. A source electrode 16 is formed in contact with second region 2 at second side surface 41 and second bottom surface 42.

According to the method for manufacturing silicon carbide semiconductor device 100 according to (14), source electrode 16 is in contact with second region 2 at second side surface 41 and second bottom surface 42. Hence, a contact area between source electrode 16 and second region 2 can be increased as compared with a case where source electrode 16 is in contact with second region 2 only at first main surface 51. As a result, contact resistance between source electrode 16 and second region 2 can be reduced. Moreover., second region 2 is in contact with source electrode 16 while extending via first region 1. Accordingly, second region 2 and source electrode 16 can have the same potential. As a result, reverse transfer capacitance of the silicon carbide semiconductor device can be suppressed from being increased. Further, second region 2 serves to suppress an electric field from being concentrated at a corner portion between first side surface 31 and first bottom surface 32 of gate trench 30. As a result, damage to gate insulating film 15 can be reduced.

(23) In the method for manufacturing silicon carbide semiconductor device 100 according to (22), gate trench 30 and source trench 40 may be formed simultaneously.

Accordingly, the manufacturing process for silicon carbide semiconductor device 100 can be shortened as compared with a case where gate trench 30 and source trench 40 are formed separately.

(24) In the method for manufacturing silicon carbide semiconductor device 100 according to (22) or (23), gate trench 30 and source trench 40 may be formed by thermal etching.

(25) The method for manufacturing silicon carbide semiconductor device 100 according to any one of (22) to (24) may further include performing activation annealing to silicon carbide substrate 10 after the forming of second region 2 and before the forming of gate insulating film 15. That is, gate insulating film 15 is formed after the activation annealing. Accordingly, gate insulating film 15 can be suppressed from being rough by the activation annealing. As a result, reliability of gate insulating film 15 formed in gate trench 30 can be improved.

(26) In the method for manufacturing silicon carbide semiconductor device 100 according to any one of (22) to (25), the forming of second region 2 may include: performing ion implantation on a condition of first energy and a first dose amount; and performing ion implantation using second energy higher than the first energy. By performing the ion implantation on a condition of the second dose amount lower than the first dose amount, a time required to form a lower portion of the second region that hardly contributes to reduction of the contact resistance can be shortened.

(27) A method for manufacturing a silicon carbide semiconductor device 100 according to one embodiment of the present disclosure includes the following steps. A silicon carbide substrate 10 having a first main surface 51 and a second main surface 52 opposite to first main surface 51 is prepared. A gate trench 30 and a source trench 40 are formed simultaneously in first main surface 51 by thermal etching. Gate trench 30 is defined by a first side surface 31 continuous to first main surface 51 and a first bottom surface 32 continuous to first side surface 31. Source trench 40 is defined by a second side surface 41 continuous to first main surface 51 and a second bottom surface 42 continuous to second side surface 41. Silicon carbide substrate 10 includes: a drift region 12 having a first conductivity type; a body region 13 provided on drift region 12 and having a second conductivity type different from the first conductivity type; a source region 14 on body region 13, source region 14 being separated from drift region 12 by body region 13, source region 14 having the first conductivity type; and a first region 1 between second bottom surface 42 and second main surface 52, first region 1 having the second conductivity type. A second region 2 is formed by performing ion implantation to second side surface 41 and second bottom surface 42, second region 2 being in contact with first region 1, second region 2 constituting at least a portion of second side surface 41. and second bottom surface 42, second region 2 having the second conductivity type. Activation annealing is performed to silicon carbide substrate 10 after the forming of second region 2. A gate insulating film 15 is formed after the performing of the activation annealing to silicon carbide substrate 10, gate insulating film 15 being in contact with drift region 12, body region 13, and source region 14 at first side surface 31, gate insulating film 15 being in contact with drift region 12 at first bottom surface 32. A source electrode 16 is formed in contact with second region 2 at second side surface 41 and second bottom surface 42. The forming of second region 2 includes: performing ion implantation on a condition of first energy and a first dose amount; and performing ion implantation on a condition of second energy and a second dose amount, the second energy being higher than the first energy, the second dose amount being lower than the first dose amount.

### [Details of Embodiment of the Present Disclosure]

The following describes details of an embodiment (hereinafter, referred to as “the present embodiment”) of the present disclosure based on figures. It should be noted that in the below-described figures, the same or corresponding portions are given the same reference characters and are not described repeatedly.

First, the following describes a configuration of a MOSFET serving as an exemplary silicon carbide semiconductor device according to the present embodiment.

As shown in FIG. 1, a MOSFET 100 according to the present embodiment mainly has a silicon carbide substrate 10, a gate insulating film 15, a gate electrode 27, an interlayer insulating film 22, a source electrode 16, a source interconnection 19, and a drain electrode 20. Silicon carbide substrate 10 includes a silicon carbide single crystal substrate 11, and a silicon carbide epitaxial layer 24 provided on silicon carbide single crystal substrate 11. Silicon carbide substrate 10 has a first main surface 51 and a second main surface 52 opposite to first main surface 51. Silicon carbide epitaxial layer 24 constitutes first main surface 51. Silicon carbide single crystal substrate 11 constitutes second main surface 52.

First main surface 51 corresponds to a {0001} plane or a plane angled off by less than or equal to 8° relative to the {0001} plane, for example. For example, first main surface 51 may correspond to a (000-1) plane or a (0001) plane, may correspond to a plane angled off by more than or equal to 2° and less than or equal to 8° relative to the (000-1) plane, or may correspond to a plane angled off by more than or equal to 2° and less than or equal to 8° relative to the (0001) plane. The maximum diameter of first main surface 51 is, for example, more than or equal to 100 mm, and is preferably more than or equal to 150 mm. Each of silicon carbide single crystal substrate 11 and silicon carbide epitaxial layer 24 is hexagonal silicon carbide of polytype 4H, for example. Silicon carbide single crystal substrate 11 includes an n type impurity such as nitrogen and has an n type conductivity, for example.

A gate trench 30 and a source trench 40 are provided in first main surface 51. Gate trench 30 is defined by a first side surface 31 continuous to first main surface 51, and a first bottom surface 32 continuous to first side surface 31. Source trench 40 is defined by a second side surface 41 continuous to first main surface 51, and a second bottom surface 42 continuous to second side surface 41. Silicon carbide epitaxial layer 24 mainly includes a drift region 12, a body region 13, a source region 14, a first region 1, and a second region 2.

Drift region 12 includes an n type impurity (first conductivity type impurity) such as nitrogen and has an n type conductivity (first conductivity type), for example. The concentration of the n type impurity of drift region 12 is about 7×10¹⁵ cm⁻³, for example. The concentration of the n type impurity of silicon carbide single crystal substrate 11 may be higher than the concentration of the n type impurity of drift region 12.

Body region 13 is located on drift region 12. Body region 13 includes a p type impurity (second conductivity type impurity) such as aluminum and has a p type conductivity (second conductivity type), for example. The concentration of the p type impurity of body region 13 may be lower than the concentration of the n type impurity of drift region 12. A channel can be formed at a region of body region 13 facing gate insulating film 15.

Source region 14 is located on body region 13. The bottom surface of source region 14 is in contact with the top surface of body region 13. Source region 14 is separated from drift region 12 by body region 13. Source region 14 includes an n type impurity such as nitrogen or phosphorus, and has the n type conductivity, for example. Source region 14 constitutes a portion of first main surface 51 of silicon carbide substrate 10. The concentration of then type impurity of source region 14 may be higher than the concentration of the n type impurity of drift region 12.

First region 1 is located between second bottom surface 42 of source trench 40 and second main surface 52. First region 1 includes a p type impurity such as aluminum, and has the p type conductivity, for example. First region 1 faces second side surface 41 and second bottom surface 42, for example. First region 1 extends along the extending direction of source trench 40, for example.

Second region 2 is in contact with first region 1, drift region 12, body region 13, and source region 14. Second region 2 includes a p type impurity such as aluminum, and has the p type conductivity, for example. The concentration of the p type impurity of second region 2 is more than or equal to 1×10¹⁹ cm⁻³ and less than or equal to 2×10²⁰ cm⁻³, for example. Second region 2 connects first region 1 to source electrode 16. When first region 1 is in a floating state, an electric line of force from drain electrode 20 enters gate electrode 27 to form a capacitance (reverse transfer capacitance) between gate electrode 27 and drain electrode 20. According to the embodiment of the present disclosure, first region 1 has a source potential when first region 1 is grounded. Therefore, the electric tine of force from drain electrode 20 enters source electrode 16. In that case, a capacitance between drain electrode 20 and source electrode 16 is formed; however, this capacitance does not affect a switching characteristic. Second region 2 constitutes second side surface 41 and second bottom surface 42, for example. Second region 2 may constitute a portion of first main surface 51. Second region 2 is provided to extend to first region 1 through source region 14 and body region 13. Second region 2 extends along the extending direction of source trench 40, for example.

Second region 2 has a third region 3 and a fourth region 4. Third region 3 is a region formed to overlap with first region 1. Hence, the concentration of the p type impurity in third region 3 may be higher than the concentration of the p type impurity in fourth region 4. Third region 3 is surrounded by first region 1. Fourth region 4 is continuous to third region 3. Fourth region 4 is in contact with drift region 12.

The concentrations of the p type and n type impurities in the above-described impurity regions can be measured by SIMS (Secondary Ion Mass Spectrometry), for example.

As shown in FIG. 1, in a cross sectional view (field of view seen in a direction parallel to second main surface 52), first side surface 31 may be inclined relative to first bottom surface 32 such that the width of gate trench 30 is narrowed in a tapered form as gate trench 30 extends from first main surface 51 toward second main surface 52. An angle θ1 of first side surface 31 relative to first bottom surface 32 is more than or equal to 50° and less than or equal to 65°, for example. First side surface 31 may correspond to a plane inclined by more than or equal to 50° and less than or equal to 65° relative to the {0001} plane, for example. Alternatively, first side surface 31 may be substantially perpendicular to first main surface 51. First bottom surface 32 may he substantially parallel to first main surface 51.

Gate insulating film 15 is provided in gate trench 30. Gate insulating film 15 is in contact with drift region 12, body region 13, and source region 14 at first side surface 31, and is in contact with drift region 12 at first bottom surface 32. Gate insulating film 15 is a thermal oxidation film, for example. Gate insulating film 15 may be in contact with source region 14 at first main surface 51. Gate insulating film 15 is composed of a material including silicon dioxide, for example. The thickness of the portion of gate insulating film 15 in contact with first bottom surface 32 may he larger than the thickness of the portion of gate insulating film 15 in contact with first side surface 31.

Gate electrode 27 is provided on gate insulating film 15 in gate trench 30. Gate electrode 27 is composed of polysilicon including an impurity, for example. Gate electrode 27 is provided to face first main surface 51, first side surface 31, and first bottom surface 32, for example.

Source electrode 16 is provided in source trench 40. Source electrode 16 is in contact with each of second side surface 41 and second bottom surface 42, and is in contact with a portion of first main surface 51. In other words, source electrode 16 is in contact with second region 2 at second side surface 41, second bottom surface 42, and first main surface 51. Source electrode 16 is in contact with source region 14 at first main surface 51. Source electrode 16 is composed of a material including TiAlSi, for example. Source electrode 16 may be composed of a material including NiSi. Preferably, source electrode 16 is in ohmic junction with both source region 14 and second region 2. A contact area between source electrode 16 and second region 2 may be larger than a contact area between source electrode 16 and source region 14.

As shown in FIG. 1, in the cross sectional view, second side surface 41 may be inclined relative to second bottom surface 42 such that the width of source trench 40 is narrowed in a tapered form as gate trench 30 extends from first main surface 51 toward second main surface 52. An angle θ2 of second side surface 41 relative to second bottom surface 42 is more than or equal to 50° and less than or equal to 65°, for example. Second side surface 41 may correspond to a plane inclined by more than or equal to 50° and less than or equal to 65° relative to the {0001} plane, for example. Alternatively, second side surface 41 may be substantially perpendicular to first main surface 51. Second bottom surface 42 may be substantially parallel to first main surface 51.

Source interconnection 19 is in contact with source electrode 16 in source trench 40. Source interconnection 19 is composed of a material including aluminum, for example. Source interconnection 19 faces both second side surface 41 and second bottom surface 42. Source interconnection 19 covers interlayer insulating film 22.

Interlayer insulating film 22 is provided in contact with gate electrode 27, gate insulating film 15, and source interconnection 19. Interlayer insulating film 22 is composed of a material including silicon dioxide, for example. Interlayer insulating film 22 electrically insulates between gate electrode 27 and source electrode 16. Drain electrode 20 is in contact with silicon carbide single crystal substrate 11 at second main surface 52, and is electrically connected to drift region 12. Drain electrode 20 is composed of a material including NiSi or TiAlSi, for example.

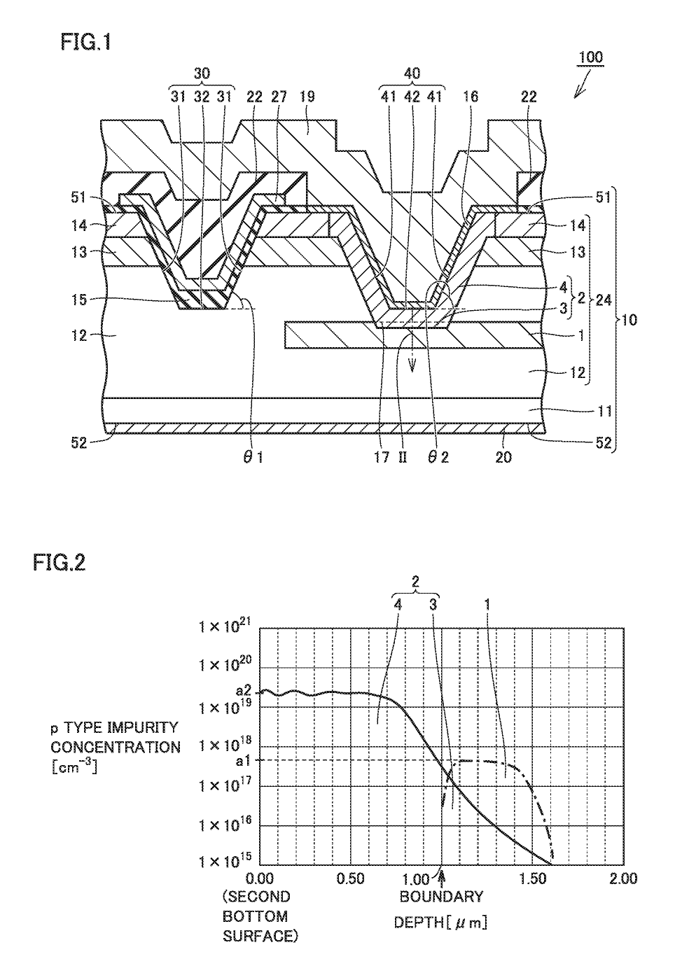

FIG. 2 shows a p type impurity concentration distribution of each of first region 1 and second region 2 in a direction along an arrow II of FIG. 1. In FIG. 2, an alternate long and short dash line represents a p type impurity concentration profile in a step of forming first region 1, whereas a solid line represents a p type impurity concentration profile in a step of forming second region 2. As shown in FIG. 2, second region 2 includes: third region 3 overlapping with first region 1; and fourth region 4 between third region 3 and second bottom surface 42. In a range from second bottom surface 42 (location with a depth of 0 μm) to a depth of about 0.6 μm, the p type impurity concentration of fourth region 4 is substantially constant. In a region from a depth of about 0.6 μm to a depth of about 1 μm, the p type impurity concentration of fourth region 4 is decreased monotonously in the direction from second bottom surface 42 toward second main surface 52. Fourth region 4 is formed by five-stage ion implantation, for example. Concentration a2 of the p type impurity of fourth region 4 in second bottom surface 42 is more than or equal to 1×10¹⁹ cm⁻³ and less than or equal to 2×10²⁰ cm⁻³, for example. Maximum concentration al of the p type impurity of first region 1 is more than or equal to 1×10¹⁷ cm⁻³ and less than 1×10¹⁹ cm⁻³, for example. The maximum concentration of the p type impurity of fourth region 4 is higher than the maximum concentration of the p type impurity of first region 1. In the direction perpendicular to second main surface 52, a distance between second bottom surface 42 and boundary 17 (see FIG. 1) between fourth region 4 and third region 3 is about 1.0 μm. The concentration of the p type impurity of boundary 17 between fourth region 4 and third region 3 is more than or equal to 1×10¹⁷ cm⁻³ and less than or equal to 1×10¹⁸ cm⁻³, for example.

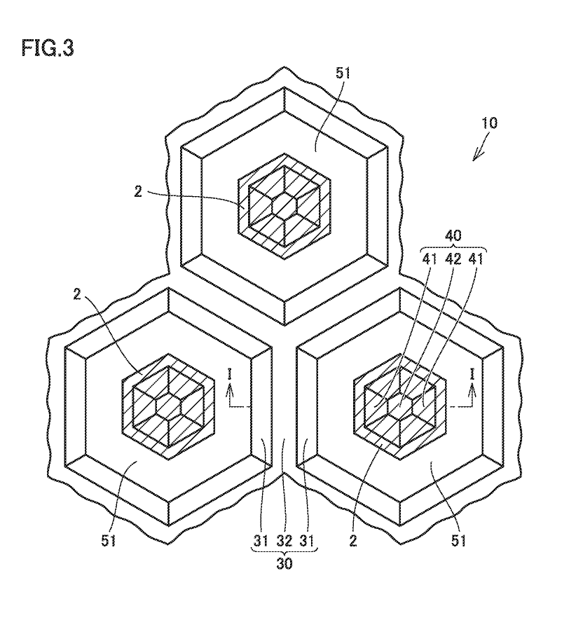

As shown in FIG. 3, in a plan view (field of view seen in the direction perpendicular to second main surface 52), source trench 40 has a hexagonal shape, for example. Gate trench 30 is provided between two adjacent source trenches 40, First main surface 51 connects second side surface 41 of source trench 40 to first side surface 31 of gate trench 30. Gate trench 30 has a honeycomb shape, for example. Gate trench 30 may surround source trench 40, In FIG. 3, each region indicated by hatching is second region 2. As shown in FIG. 3, in the plan view, second region 2 has a hexagonal shape, for example. Second region 2 is provided to surround source trench 40. Gate trench 30 is provided to surround second region 2.

### (First Modification of Silicon Carbide Semiconductor Device)

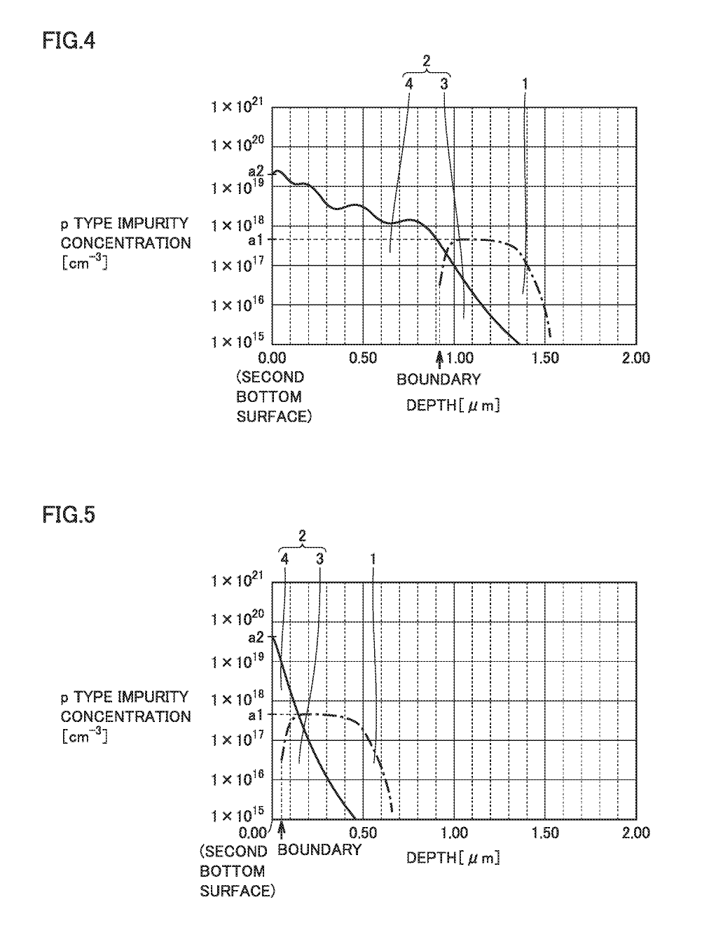

Next, the following describes a configuration of a first modification of MOSFET 100. FIG. 4 shows a first modification of the p type impurity concentration distribution of each of first region 1 and second region 2 in the direction along arrow II of FIG. 1. As shown in FIG. 4, in a range from second bottom surface 42 (location with a depth of 0 μm) to a depth of about 0.8 μm, in the direction from second bottom surface 42 toward second main surface 52, the p type impurity concentration of fourth region 4 is decreased gradually while alternately exhibiting maximum and minimum values. In a region from a depth of about 0.8 μm to a depth of about 0.92 μm, the p type impurity concentration of fourth region 4 is decreased monotonously in the direction from second bottom surface 42 toward second main surface 52. Fourth region 4 is formed by four-stage ion implantation, for example. In the direction perpendicular to second main surface 52, the distance between second bottom surface 42 and boundary 17 (see FIG. 1) between fourth region 4 and third region 3 is about 0.92 μm. The concentration of the p type impurity of boundary 17 between fourth region 4 and third region 3 is more than or equal to 1×10¹⁷ cm⁻³ and less than or equal to 1×10¹⁸ cm⁻³, for example.

### (Second Modification of Silicon Carbide Semiconductor Device)

Next, the following describes a configuration of a second modification of MOSFET 100. FIG. 5 shows a second modification of the p type impurity concentration distribution of each of first region 1 and second region 2 in the direction along arrow II of FIG. 1. As shown in FIG. 5, in a range from second bottom surface 42 (location with a depth of 0 μm) to a depth of about 0.05 μm, the p type impurity concentration of fourth region 4 is decreased monotonously in the direction from second bottom surface 42 toward second main surface 52. Fourth region 4 is formed by one-stage ion implantation, for example. In the direction perpendicular to second main surface 52, the distance between second bottom surface 42 and boundary 17 (see FIG. 1) between fourth region 4 and third region 3 is about 0.05 μm. The concentration of the p type impurity of boundary 17 between fourth region 4 and third region 3 is more than or equal to 1×10¹⁸ cm⁻³ and less than or equal to 1×10¹⁹ cm⁻³, for example. When the distance between first region 1 and second bottom surface 42 is short (for example, about 0.1 μm), second region 2 can be formed by one-stage ion implantation.

### (Third Modification of Silicon Carbide Semiconductor Device)

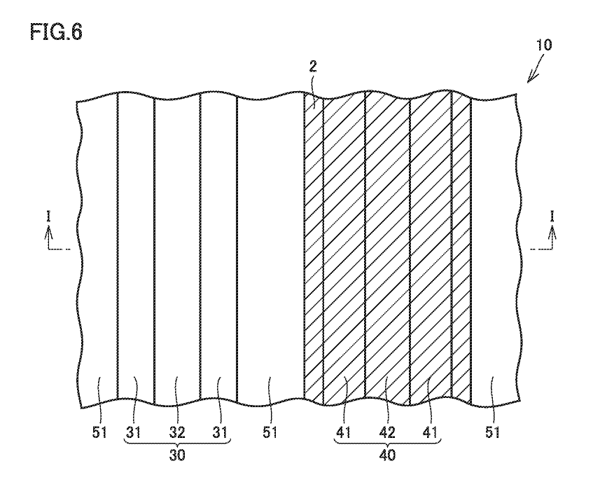

Next, the following describes a configuration of a third modification of MOSFET 100. As shown in FIG. 6, in a plan view, the shape of each of source trench 40 and gate trench 30 may be a stripe shape. Gate trench 30 may extend in a direction parallel to the extending direction (upward downward direction in FIG. 6) of source trench 40. Gate trench 30 and source trench 40 may be provided alternately along a direction (horizontal direction in FIG. 6) perpendicular to the extending direction of source trench 40. In FIG. 6, a region indicated by hatching is second region 2. As shown in FIG. 6, in the plan view, the shape of second region 2 is a stripe shape, for example. Second region 2 is provided along the extending direction of source trench 40.

### (Fourth Modification of Silicon Carbide Semiconductor Device)

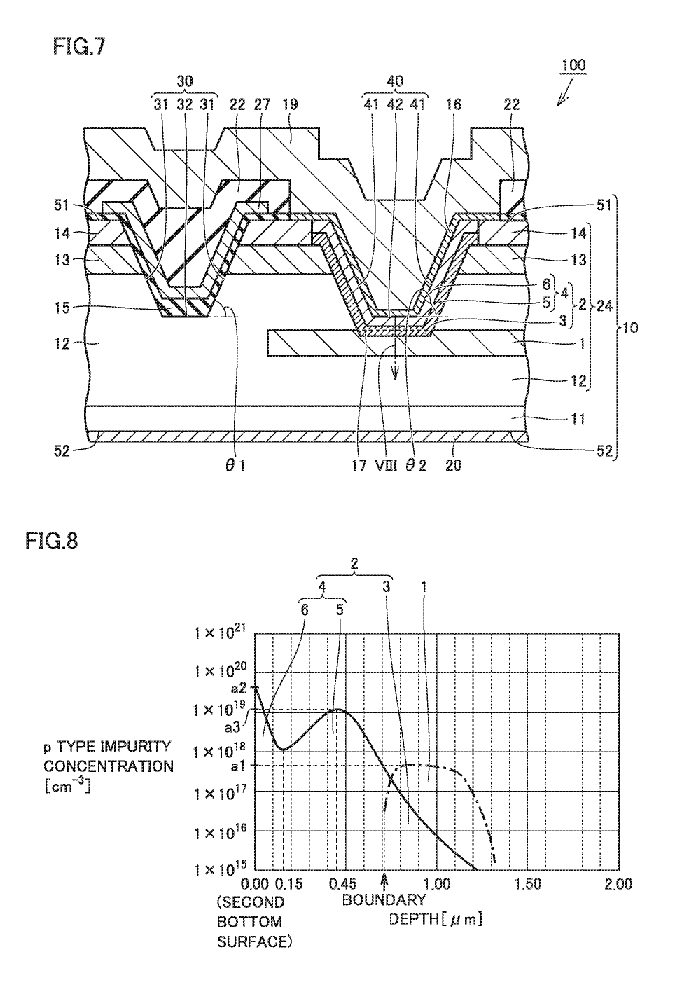

Next, the following describes a configuration of a fourth modification of MOSFET 100. As shown in FIG. 7, second region 2 may include: third region 3 in contact with first region 1; and fourth region 4 continuous to third region 3 and in contact with drift region 12. Fourth region 4 includes: a fifth region 5 in contact with both drift region 12 and the third region; and a sixth region 6 interposed between fifth region 5 and source trench 40. Sixth region 6 is in contact with source electrode 16 at first main surface 51, second side surface 41, and second bottom surface 42.

FIG. 8 shows a p type impurity concentration distribution of each of first region 1 and second region 2 in a direction along an arrow V1 of FIG. 7. In FIG. 8, an alternate long and short dash line represents a p type impurity concentration profile in a step of forming first region 1, whereas a solid line represents a p type impurity concentration profile in a step of forming second region 2. As shown in FIG. 8, second region 2 has third region 3 and fourth region 4. Fourth region 4 has fifth region 5 and sixth region 6. As shown in FIG. 8, the p type impurity concentration of fourth region 4 may exhibit the minimum value at a location separated by about 0.15 μm from second bottom surface 42, and may exhibit the maximum value at a location separated by about 0.45 μm from second bottom surface 42. Fourth region 4 is formed by two-stage ion implantation, for example. In the direction perpendicular to second main surface 52, the distance between second bottom surface 42 and boundary 17 (see FIG. 7) between fourth region 4 and third region 3 is about 0.7 μm. The concentration of the p type impurity of boundary 17 between fourth region 4 and third region 3 is more than or equal to 1×10¹⁷ cm⁻³ and less than or equal to 1×10¹⁸ cm⁻³, for example.

In fourth region 4, fifth region 5 is located at the second main surface 52 side relative to the location exhibiting the minimum value of the p type impurity concentration, and sixth region 6 is located at the second bottom surface 42 side relative to the location exhibiting the minimum value of the p type impurity concentration. Maximum concentration a3 of the p type impurity of fifth region 5 is lower than maximum concentration a2 of the p type impurity of sixth region 6. Maximum concentration a3 of the p type impurity of fifth region 5 is more than or equal to 1×10¹⁷ cm⁻³ and less than 2×10¹⁹ cm⁻³; for example. Maximum concentration a2 of the p type impurity of sixth region 6 is more than or equal to 1×10¹⁹ cm⁻³ and less than or equal to 2×10²⁰ cm⁻³, for example. Third region 3 overlaps with first region 1. As shown in FIG. 8, concentration a2 of the p type impurity in second bottom surface 42 is higher than the concentration of the p type impurity in boundary 17 between third region 3 and fourth region 4.

### (Fifth Modification of Silicon Carbide Semiconductor Device)

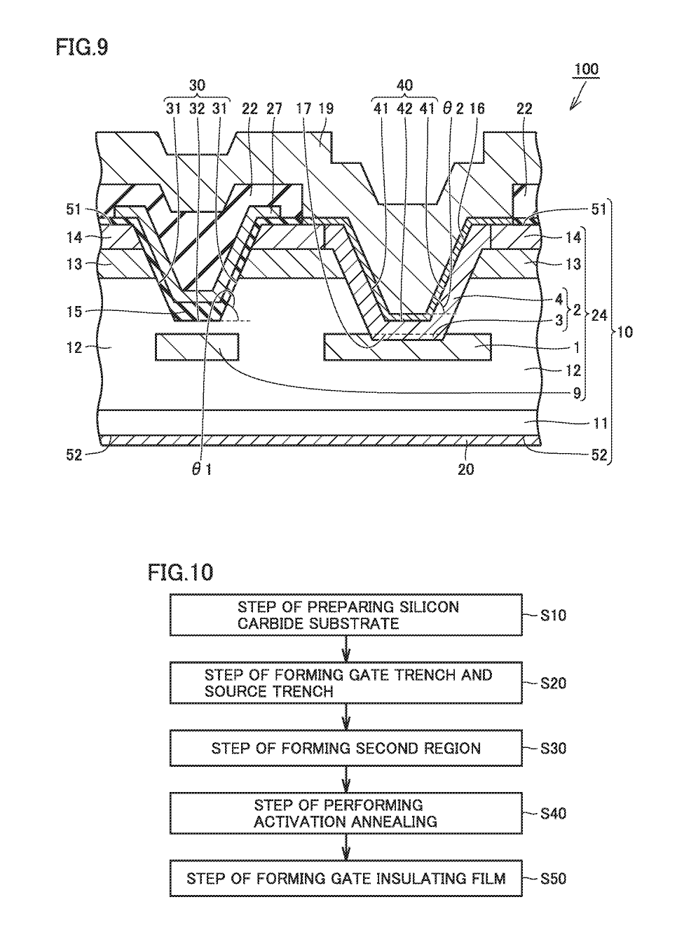

Next, the following describes a configuration of a fifth modification of MOSFET 100. As shown in FIG. 9, silicon carbide substrate 10 may further include a ninth region 9. Ninth region 9 is located between first bottom surface 32 of gate trench 30 and second main surface 52. Ninth region 9 includes a p type impurity such as aluminum, and has the p type conductivity, for example. The maximum concentration of the p type impurity of ninth region 9 is substantially the same as the maximum concentration of the p type impurity of first region 1. Ninth region 9 may be formed simultaneously with first region 1. A distance between the upper surface of ninth region 9 and first bottom surface 32 is substantially the same as a distance between the upper surface of first region 1 and second bottom surface 42.

Ninth region 9 faces first bottom surface 32, for example. Ninth region 9 extends along the extending direction of gate trench 30, for example. Ninth region 9 is electrically connected to first region 1. Ninth region 9 is separated from first bottom surface 32. Drift region 12 is located between ninth region 9 and first bottom surface 32. Ninth region 9 serves to reduce an electric field concentrate at a corner portion formed by first side surface 31 and first bottom surface 32 of gate trench 30.

### (Sixth Modification of Silicon Carbide Semiconductor Device)

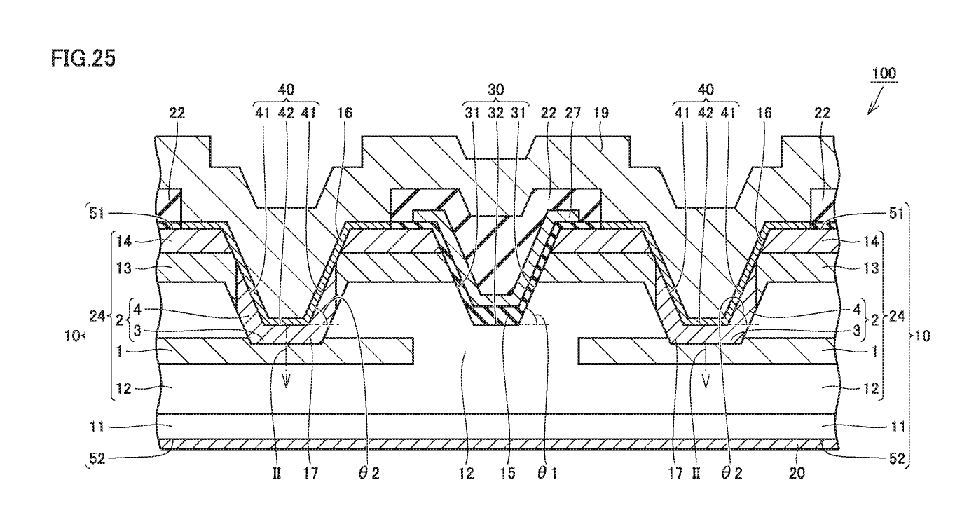

Next, the following describes a configuration of a sixth modification of MOSFET 100. As shown in FIG. 25, second region 2 may be separated from first main surface 51. In other words, second region 2 does not constitute first main surface 51. Second region 2 is in contact with body region 13, and is separated from source region 14. Source region 14, body region 13., and second region 2 are in contact with source electrode 16 at second side surface 41. Second side surface 41 is constituted of source region 14, body region 13, and second region 2. In the direction parallel to second main surface 52, the width of second region 2 may be smaller than the width of the opening of source trench 40. The boundary between second region 2 and body region 13 may be located at the second main surface 52 side relative to a boundary between source region 14 and body region 13 in the direction perpendicular to second main surface 52. Accordingly, contact resistance between each of source region 14 and second region 2 and source electrode 16 can be reduced.

### (Seventh Modification of Silicon Carbide Semiconductor Device)

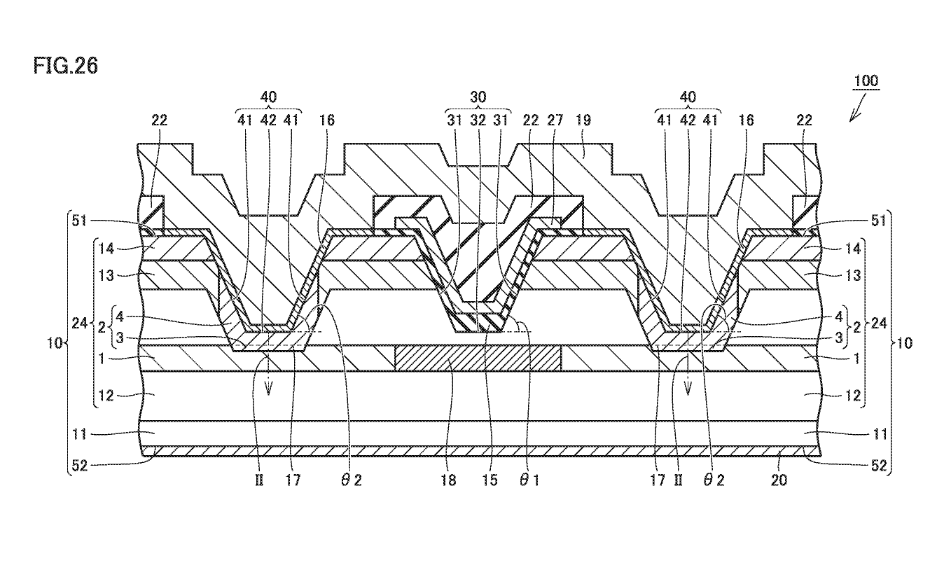

Next, the following describes a configuration of a seventh modification of MOSFET 100. As shown in FIG. 26, silicon carbide substrate 10 may have an impurity region 18. Impurity region 18 is a JFET (Junction Field Effect Transistor) region. Impurity region 18 includes an n type impurity (first conductivity type impurity) such as nitrogen, and has the n type conductivity (first conductivity type), for example. Impurity region 18 is located between first bottom surface 32 and second main surface 52. Impurity region 18 faces first region 1. In a cross sectional view, impurity region 18 is located between a pair of first regions 1. Impurity region 18 may be in contact with first region 1. In the cross sectional view, impurity region 18 may be interposed between the pair of first regions 1.

The concentration of the first conductivity type impurity in impurity region 18 is higher than the concentration of the first conductivity type impurity in drift region 12. The concentration of the n type impurity in impurity region 18 is more than or equal to 1×10¹⁵ cm⁻³ and less than or equal to 5×10¹⁷ cm⁻³, for example. The thickness of impurity region 18 is substantially the same as that of first region 1. Impurity region 18 may face both first bottom surface 32 and first side surface 31. In the direction parallel to second main surface 52, the width of impurity region 18 may be larger than the width of first bottom surface 32. Accordingly, blocking resistance by first region 1 can be suppressed. As a result, on resistance can be reduced.

### (Eighth Modification of Silicon Carbide Semiconductor Device)

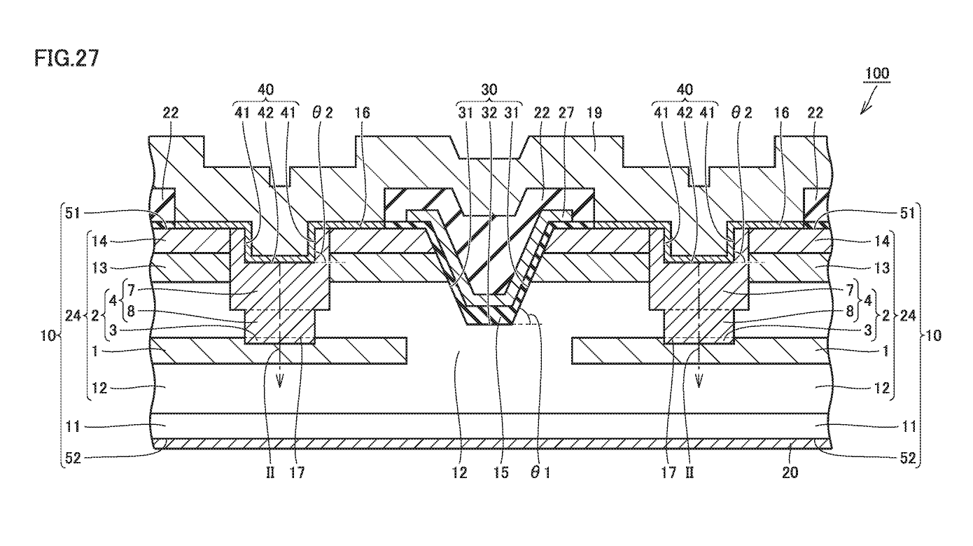

Next, the following describes a configuration of an eighth modification of MOSFET 100. As shown in FIG. 27, second side surface 41 of source trench 40 may extend substantially perpendicularly to first main surface 51. An angle θ2 of second side surface 41 relative to second bottom surface 42 is more than 65° and less than or equal to 90°, for example. Angle θ2 may be more than or equal to 70° or more than or equal to 80°. Second region 2 includes third region 3 and fourth region 4. Fourth region 4 has a seventh region 7 and an eighth region 8. Eighth region 8 is continuous to third region 3. Seventh region 7 is located opposite to third region 3 relative to eighth region 8. Eighth region 8 is interposed between seventh region 7 and third region 3. In the direction perpendicular to second main surface 52, a boundary between seventh region 7 and eighth region 8 may be located between body region 13 and first region 1.

In the direction parallel to second main surface 52, the width of seventh region 7 may be larger than the width of eighth region 8. The width of eighth region 8 may be substantially the same as that of third region 3. The width of seventh region 7 may be larger than the width of third region 3. The width of seventh region 7 may be larger than the width of second bottom surface 42. In the direction perpendicular to second main surface 52, second bottom surface 42 may be located between source region 14 and drift region 12. In other words, in the direction perpendicular to second main surface 52, second bottom surface 42 may be located between the boundary between source region 14 and body region 13 and the boundary between body region 13 and drift region 12. A plane including second bottom surface 42 may cross body region 13. In the direction parallel to second main surface 52, the width of the opening of source trench 40 is smaller than the width of the opening of gate trench 30. Accordingly, a cell pitch can be reduced. Moreover, since second bottom surface 42 of source trench 40 is disposed to cross body region 13, second bottom surface 42 of source trench 40 is surrounded by body region 13. Accordingly, source electrode 16 can be suppressed from being short-circuited with drain electrode 20 via drift region 12.

### (Ninth Modification of Silicon Carbide Semiconductor Device)

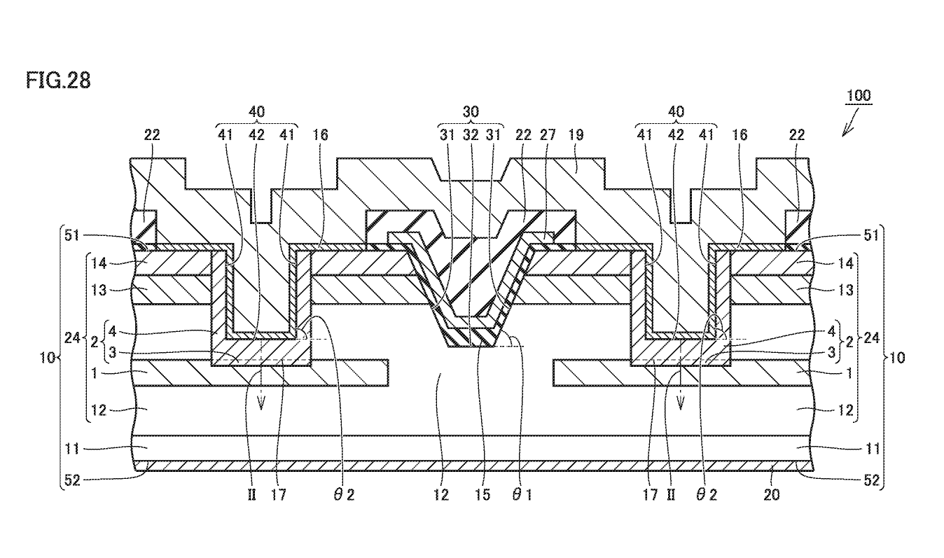

Next, the following describes a configuration of a ninth modification of MOSFET 100. As shown in FIG. 28, the depth of source trench 40 may be substantially the same as that of gate trench 30. Second side surface 41 of source trench 40 may extend substantially perpendicularly to first main surface 51. In the direction perpendicular to second main surface 52, second bottom surface 42 may be located between body region 13 and first region 1. In other words, in the direction perpendicular to second main surface 52, second bottom surface 42 may be located between the boundary between body region 13 and drift region 12 and the boundary between fourth region 4 and third region 3. A plane including second bottom surface 42 may cross drift region 12. In the direction parallel to second main surface 52, the width of the opening of source trench 40 is smaller than the width of the opening of gate trench 30. Accordingly, a cell pitch can be reduced.

### (Tenth Modification of Silicon Carbide Semiconductor Device)

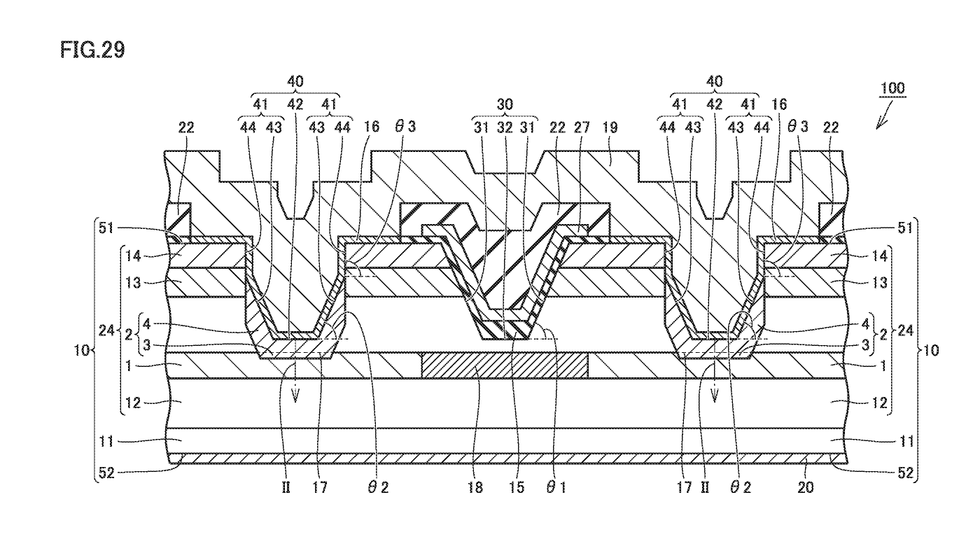

Next, the following describes a configuration of a tenth modification of MOSFET 100. As shown in FIG. 29, source trench 40 may be constituted of a trench folded to have two or more side portions. Specifically, second side surface 41 includes a first side portion 43 and a second side portion 44. First side portion 43 is continuous to second bottom surface 42. Second side portion 44 is continuous to first side portion 43. Angle θ2 of first side portion 43 relative to second bottom surface 42 may be smaller than angle θ3 of second side portion 44 relative to the plane parallel to second bottom surface 42. Angle θ2 of first side portion 43 relative to second bottom surface 42 is more than or equal to 50° and less than or equal to 65°, for example. Angle θ3 is more than 65°, and less than or equal to 90°, for example. Angle θ3 may be more than or equal to 70° or more than or equal to 80°. In the direction parallel to second main surface 52, the width of the opening of source trench 40 is smaller than the width of the opening of gate trench 30. Accordingly, a cell pitch can be reduced. Second side portion 44 may be continuous to first main surface 51. Second side portion 44 may extend substantially perpendicularly to first main surface 51. Source region 14 and body region 13 are in contact with source electrode 16 at second side portion 44. Second side portion 44 is constituted of source region 14 and body region 13. Second region 2 is in contact with source electrode 16 at first side portion 43 and second bottom surface 42. First side portion 43 and second bottom surface 42 are constituted of second region 2. Second region 2 is separated from first main surface 51. Second region 2 is in contact with body region 13, and is separated from source region 14. Accordingly, contact resistance between each of source region 14 and second region 2 and source electrode 16 can be reduced.

Silicon carbide substrate 10 may have an impurity region 18. Impurity region 18 is a HET region. Impurity region 18 includes an n type impurity (first conductivity type impurity) such as nitrogen, and has the n type conductivity (first conductivity type), for example. Impurity region 18 is located between first bottom surface 32 and second main surface 52. As shown in FIG. 29, in a cross sectional view, impurity region 18 is located between the pair of firm regions 1. The concentration of the first conductivity type impurity in impurity region 18 is higher than the concentration of the first conductivity type impurity in drift region 12. The concentration of then type impurity in impurity region 18 is more than or equal to 1×10¹⁵ cm⁻³ and less than or equal to 5×10¹⁷ cm⁻³, for example. The thickness of impurity region 18 is substantially the same as that of first region 1. Impurity region 18 may face both first bottom surface 32 and first side surface 31. In the direction parallel to second main surface 52, the width of impurity region 18 may be larger than the width of first bottom surface 32. Accordingly, blocking resistance by first region 1 cart be suppressed. As a result, on resistance can be reduced.

### (Eleventh Modification of Silicon Carbide Semiconductor Device)

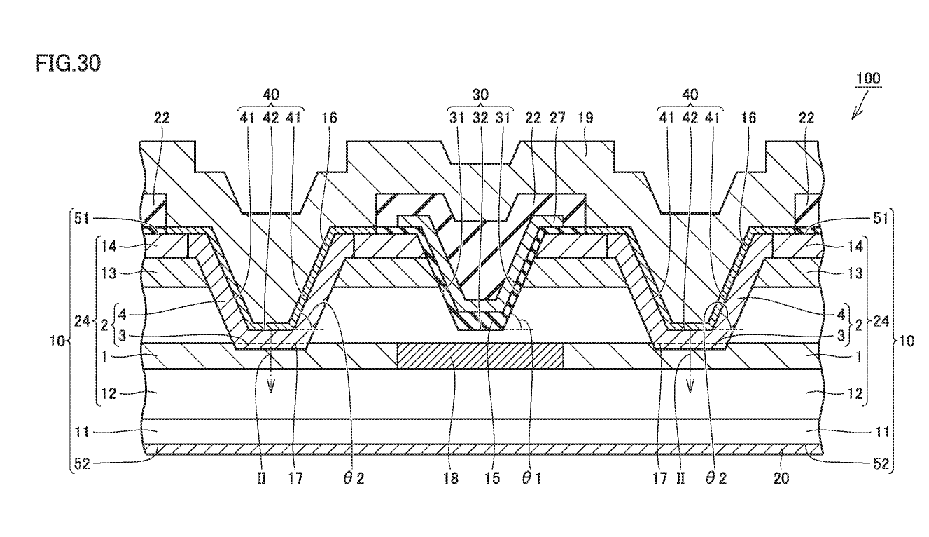

Next, the following describes a configuration of an eleventh modification of MOSFET 100. As shown in FIG. 30, silicon carbide substrate 10 may have an impurity region 18. Impurity region 18 is a JFET region. Impurity region 18 includes an n type impurity (first conductivity type impurity) such as nitrogen, and has the n type conductivity (first conductivity type), for example. Impurity region 18 is located between first bottom surface 32 and second main surface 52. Impurity region 18 faces first region 1. In a cross sectional view, impurity region 18 is located between a pair of first regions 1. Impurity region 18 may be in contact with first region 1. In the cross sectional view, impurity region 18 may be interposed between the pair of first regions 1. Second region 2 may constitute a portion of first main surface 51.

The concentration of the first conductivity type impurity in impurity region 18 is higher than the concentration of the first conductivity type impurity in drift region 12. The concentration of the n type impurity in impurity region 18 is more than or equal to 1×10¹⁵ cm⁻³ and less than or equal to 5×10¹⁷ cm⁻³, for example. The thickness of impurity region 18 is substantially the same as that of first region 1. Impurity region 18 may face both first bottom surface 32 and first side surface 31. In the direction parallel to second min surface 52, the width of impurity region 18 may be larger than the width of first bottom surface 32. Accordingly, blocking resistance by first region 1 can be suppressed. As a result, on resistance can be reduced.

### (Twelfth Modification of Silicon Carbide Semiconductor Device)

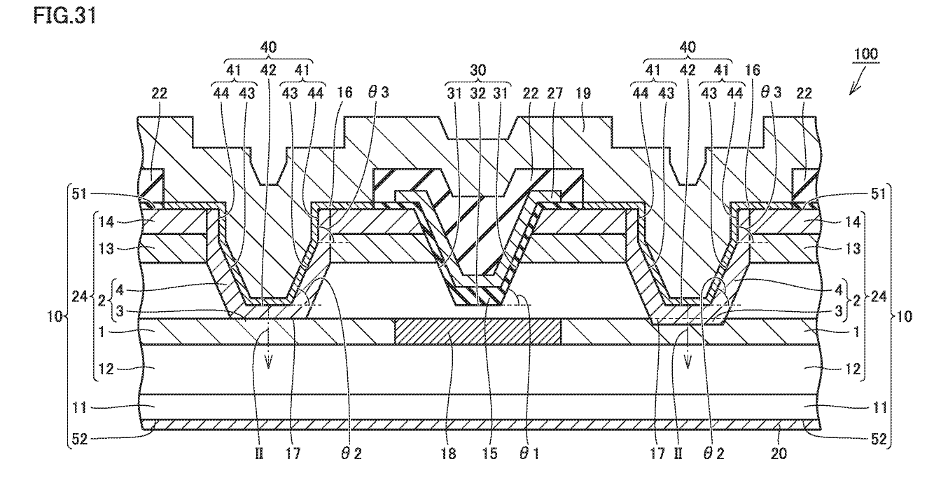

Next, the following describes a configuration of a twelfth modification of MOSFET 100. As shown in FIG. 31, source trench 40 may be constituted of a trench folded to have two or more side portions. Specifically, second side surface 41 includes first side portion 43 and second side portion 44. First side portion 43 is continuous to second bottom surface 42. Second side portion 44 is continuous to first side portion 43. Angle θ2 of first side portion 43 relative to second bottom surface 42 may be smaller than angle θ3 of second side portion 44 relative to the plane parallel to second bottom surface 42. Angle θ2 of first side portion 43 relative to second bottom surface 42 is more than or equal to 50° and less than or equal to 65°, for example. Angle θ3 is more than 65° and less than or equal to 90°, for example. Angle θ3 may be more than or equal to 70° or more than or equal to 80°. In the direction parallel to second main surface 52, the width of the opening of source trench 40 is smaller than the width of the opening of gate trench 30. Accordingly, a cell pitch can be reduced.

Second side portion 44 may be continuous to first main surface 51. Second side portion 44 may extend substantially perpendicularly to first main surface 51. Second region 2 is in contact with source electrode 16 at first side portion 43, second side portion 44, and second bottom surface 42. First side portion 43, second side portion 44, and second bottom surface 42 are constituted of second region 2. Second region 2 constitutes a portion of first main surface 51. Second region 2 is in contact with body region 13 and source region 14. Accordingly, contact resistance between second region 2 and source electrode 16 can be reduced.

### (Thirteenth Modification of Silicon Carbide Semiconductor Device)

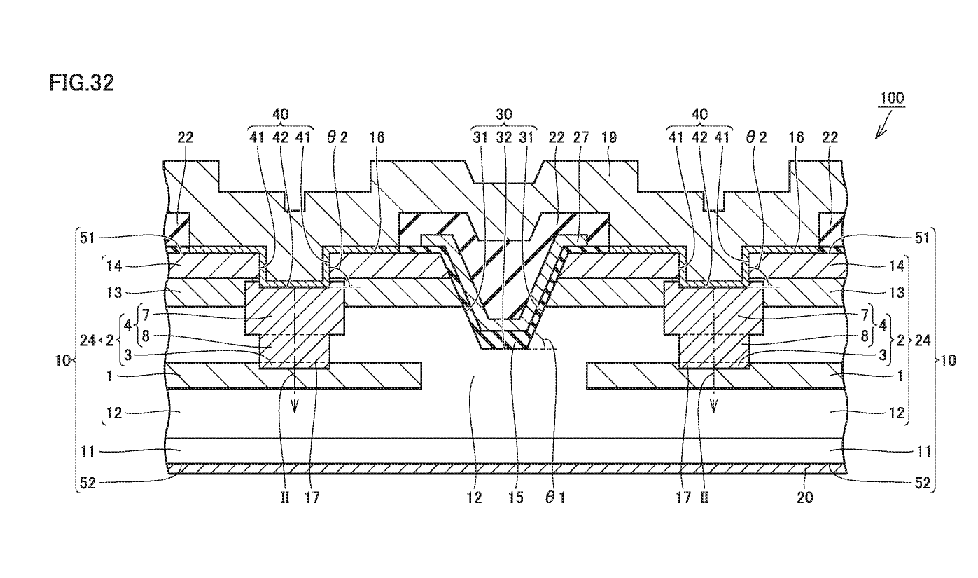

Next, the following describes a configuration of a thirteenth modification of MOSFET 100. As shown in FIG. 32, second side surface 41 of source trench 40 may extend substantially perpendicularly to first main surface 51. Angle θ2 of second side surface 41 relative to second bottom surface 42 is more than 65° and less than or equal to 90°, for example. Angle θ2 may be more than or equal to 70° or more than or equal to 80°. Second region 2 includes third region 3 and fourth region 4. Fourth region 4 has seventh region 7 and eighth region 8. Eighth region 8 is continuous to third region 3. Seventh region 7 is located opposite to third region 3 relative to eighth region 8. Eighth region 8 is interposed between seventh region 7 and third region 3. In the direction perpendicular to second main surface 52, the boundary between seventh region 7 and eighth region 8 may be located between body region 13 and first region 1. Second region 2 may be separated from first main surface 51. Source electrode 16 may be in contact with source region 14 at second side surface 41.

In the direction parallel to second main surface 52, the width of seventh region 7 may be larger than the width of eighth region 8, The width of eighth region 8 may be substantially the same as that of third region 3. The width of seventh region 7 may be larger than the width of third region 3. The width of seventh region 7 may be larger than the width of second bottom surface 42. In the direction perpendicular to second main surface 52, second bottom surface 42 may be located between source region 14 and drift region 12. In other words, in the direction perpendicular to second main surface 52, second bottom surface 42 may be located between the boundary between source region 14 and body region 13 and the boundary between body region 13 and drift region 12. A plane including second bottom surface 42 may cross body region 13. In the direction parallel to second main surface 52, the width of the opening of source trench 40 is smaller than the width of the opening of gate trench 30. Accordingly, a cell pitch can be reduced. Moreover, since second bottom surface 42 of source trench 40 is disposed to cross body region 13, second bottom surface 42 of source trench 40 is surrounded by body region 13. Accordingly, source electrode 16 can be suppressed from being short-circuited with drain electrode 20 via drift region 12.

### (Fourteenth Modification of Silicon Carbide Semiconductor Device)

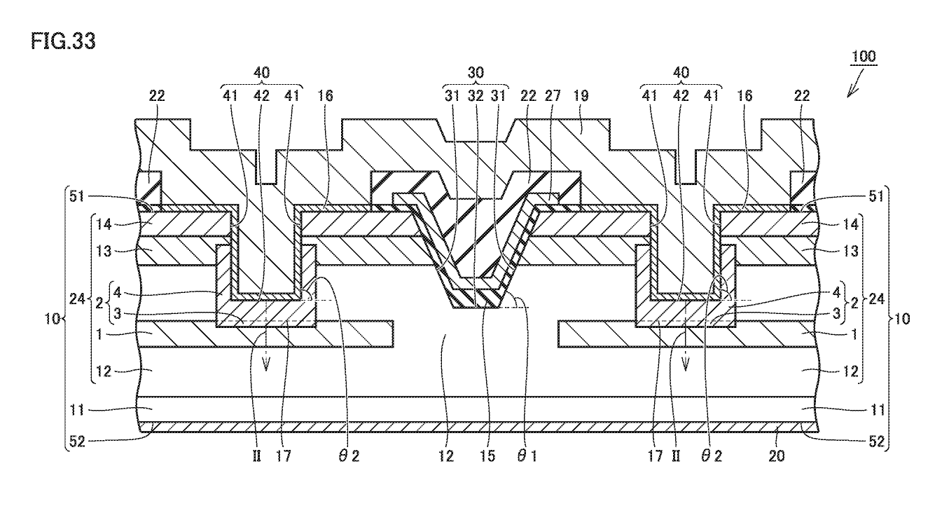

Next, the following describes a configuration of a fourteenth modification of MOSFET 100. As shown in FIG. 33, the depth of source trench 40 may be substantially the same as that of gate trench 30. Second side surface 41 of source trench 40 may extend substantially perpendicularly to first main surface 51. In the direction perpendicular to second main surface 52, second bottom surface 42 may be located between body region 13 and first region 1. In other words, in the direction perpendicular to second main surface 52, second bottom surface 42 may be located between the boundary between body region 13 and drift region 12 and the boundary between fourth region 4 and third region 3. A plane including second bottom surface 42 may cross drift region 12. Second region 2 may be separated from first main surface 51. Source electrode 16 may be in contact with source region 14 at second side surface 41. In the direction parallel to second main surface 52, the width of the opening of source trench 40 is smaller than the width of the opening of gate trench 30. Accordingly, a cell pitch can be reduced.

Next, the following describes a method for manufacturing MOSFET 100 according to the present embodiment.

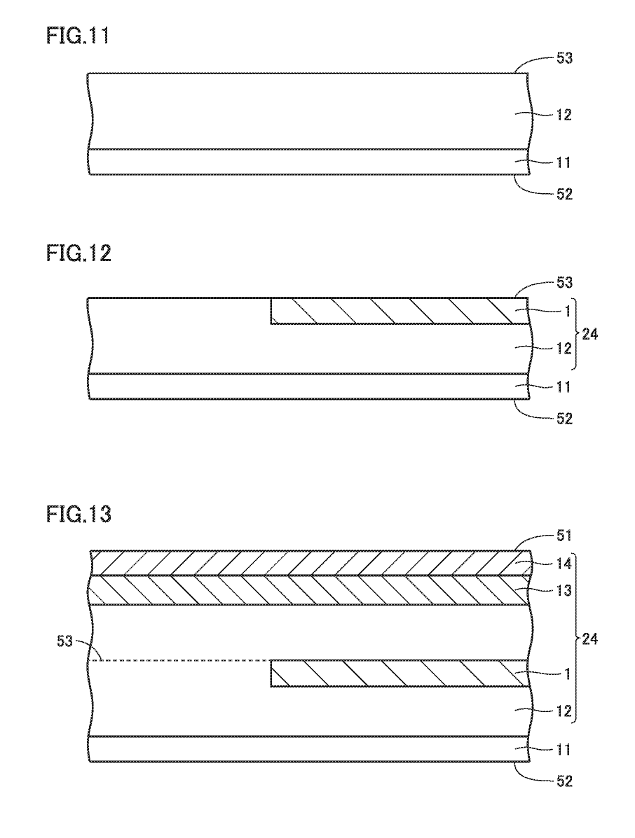

First, a step (S10: FIG. 10) of preparing a silicon carbide substrate is performed. For example, silicon carbide single crystal substrate 11 is prepared using a sublimation method. The polytype of silicon carbide single crystal substrate 11 is 4H, for example. The maximum diameter of the silicon carbide single crystal substrate is, for example, more than or equal to 100 mm, and is preferably more than or equal to 150 mm. Next, silicon carbide epitaxial layer 24 is formed on silicon carbide single crystal substrate 11. Specifically, drift region 12 is formed on silicon carbide single crystal substrate 11 (see FIG. 11) using a CVD (Chemical Vapor Deposition) method in which: a mixed gas of silane (SiH₄) and propane (C₃H₈) is used as source material gas, for example; hydrogen gas (H₂) is used as carrier gas, for example, and ammonia (NH₃) is used as dopant gas. The thickness of drift region 12 is 9 μm, for example. The concentration of nitrogen atoms included in drift region 12 is about 7×10¹⁵ cm⁻³, for example.

Next, a mask layer (not shown) is formed on surface 53 of drift region 12. The mask layer is provided with an opening above a region in which first region 1 is to be formed. Using the mask. layer, ions of a p type impurity such as aluminum are implanted into surface 53 of drift region 12. Accordingly, in drift region 12, first region 1 constituting a portion of surface 53 is formed (see FIG. 12). The thickness of first region 1 is more than or equal to 0.1 μm and less than or equal to 1.2 μm, for example. The maximum concentration of the p type impurity in first region 1 is more than or equal to 1×10¹⁶ cm⁻³ and less than 1×10¹⁹ cm⁻³. Next, the mask layer is removed from surface 53. Next, an n type region is formed on drift region 12 and first region 1 by a CND method in which: a mixed gas of silane and propane is used as source material gas, for example; hydrogen gas is used as carrier gas, for example; and ammonia is used as dopant gas.

Next, an ion implantation step is performed. Ions of a p type impurity such as aluminum are implanted into the n type region. Accordingly, body region 13 having the p type conductivity is formed. Body region 13 is formed to be separated from first region 1. Next, ions of an n type impurity such as phosphorus are implanted into body region 13. Accordingly, source region 14 having then type conductivity is formed (see FIG. 13). The thickness of source region 14 is 0.4 μm, for example. Source region 14 constitutes first main surface 51. The concentration of the n type impurity included in source region 14 is higher than the concentration of the p type impurity included in body region 13.

Next, a step (S20: FIG. 10) of forming the Rate trench and the source trench is performed. For example, a mask 60 provided with an opening above a location in which gate trench 30 (FIG. 1) and source trench 40 (FIG. 1) are to be formed is formed on first main surface 51 constituted of source region 14. Using mask 60, etching is performed to remove source region 14, body region 13, and a portion of drift region 12. An exemplary, usable etching method is reactive ion etching, in particular, inductively coupled plasma reactive ion etching. Specifically, for example, inductively coupled plasma reactive ion etching can be used in which SF₆ or mixed gas of SF₆ and O₂ is used as reactive gas. By the etching, a recess is formed in the region in which gate trench 30 and source trench 40 are to be formed. The recess includes: a side portion substantially perpendicular to first main surface 51; and a bottom portion provided to be continuous to the side portion and substantially parallel to first main surface 51.

Next, thermal etching is performed in the recess. For example, in the state in which mask 60 is formed on first main surface 51, the thermal etching can be performed by performing heating in an atmosphere including reactive gas having at least one or more types of halogen atoms. The at least one or more types of halogen atoms include at least one of chlorine (Cl) atom and fluorine (F) atom. The atmosphere includes Cl₂, BCl₃, SF₆, or CF₄, for example. For example, the thermal etching is performed using a mixed gas of chlorine gas and oxygen gas as a reactive gas, at a heat treatment temperature of, for example, more than or equal to 700° C. and less than or equal to 1000° C. It should be noted that the reactive gas may contain a carrier gas in addition to the chlorine gas and the oxygen gas. An exemplary, usable carrier gas is nitrogen gas, argon gas, helium gas, or the like.

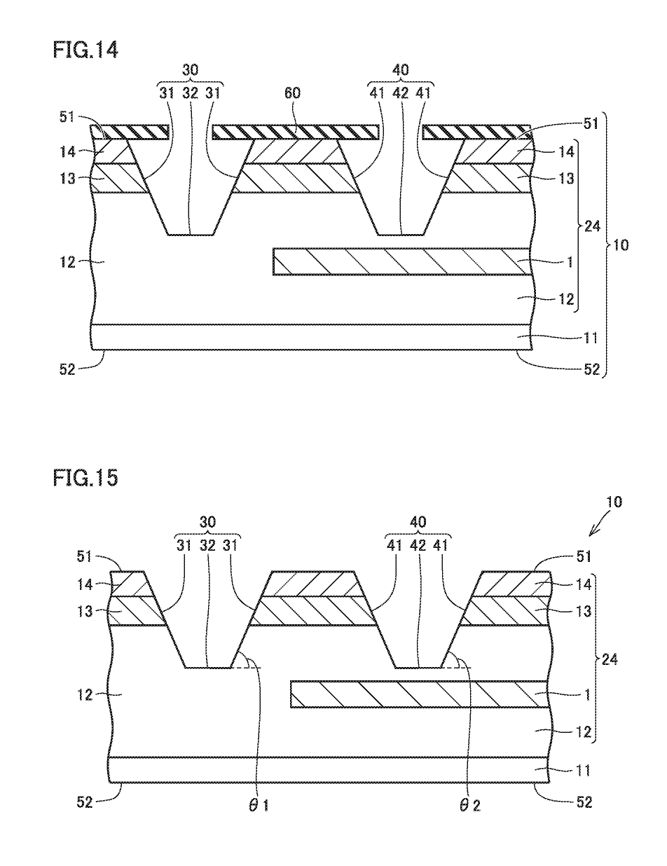

By the thermal etching, gate trench 30 and source trench 40 are formed in first main surface 51 (see FIG. 14). Preferably, gate trench 30 and source trench 40 are formed simultaneously. Gate trench 30 is defined by: first side surface 31 continuous to first main surface 51; and first bottom surface 32 continuous to first side surface 31.

First side surface 31 is constituted of source region 14, body region 13, and drill region 12. First bottom surface 32 is constituted of drift region 12. Angle θ1 of first side surface 31 relative to first bottom surface 32 is 54.7°, for example. Similarly, source trench 40 is defined by: second side surface 41 continuous to first main surface 51; and second bottom surface 42 continuous to second side surface 41. Second side surface 41 is constituted of source region 14, body region 13, and drift region 12. Second bottom surface 42 is constituted of drift region 12. Angle θ2 of second side surface 41 relative to second bottom surface 42 is 54.7°, for example. Next, mask 60 is removed from first main surface 51 (see FIG. 15).

In the manner described above, silicon carbide substrate 10 shown in FIG. 15 is prepared. Silicon carbide substrate 10 includes: drift region 12 having the n type; body region 13 provided on drift region 12 and having the p type different from the n type; source region 14 on body region 13, source region 14 being separated from drift region 12 by body region 13, source region 14 having then type; and first region 1 between second bottom surface 42 and second main surface 52, first region 1 having the p type. The silicon carbide substrate has first main surface 51 and second main surface 52 opposite thereto. First main surface 51 is constituted of source region 14. Second main surface 52 is constituted of silicon carbide single crystal substrate 11.

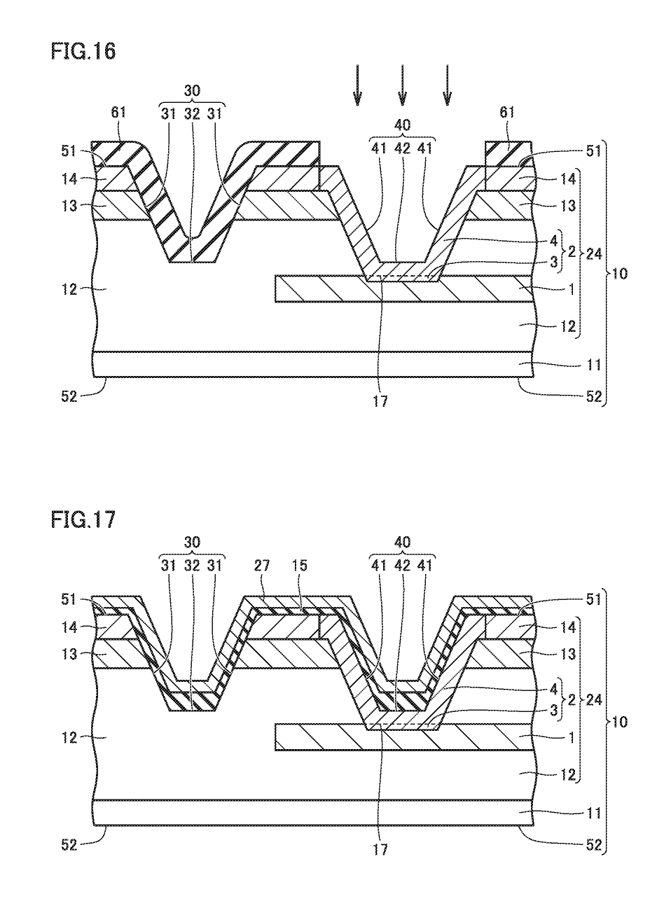

Next, a step (S30: FIG. 10) of forming the second region is performed. In the step of forming the second region, the second region is formed to have the profile of the p type impurity concentration as shown in FIG. 2, FIG. 4, and FIG. 5. First, a mask 61 provided with an opening above a region in which the second region is to be formed is formed. Mask 61 is formed to cover first main surface 51, first side surface 31, and first bottom surface 32. Next, an ion implantation step is performed. Using mask 61, ions of a p type impurity such as aluminum are implanted into second side surface 41 and second bottom surface 42 of source trench 40, for example. Accordingly, second region 2 is formed (see FIG. 16). Second region 2 is in contact with first region 1, constitutes at least a portion of second side surface 41 and second bottom surface 42, and has the p type. The ion implantation of the p type impurity is performed in a direction substantially perpendicular to first main surface 51 (direction of arrow in FIG. 16). The ions of the p type impurity are implanted into drift region 12 and first region 1 via second bottom surface 42. The ions of the p type impurity are implanted into source region 14, body region 13, and drill region 12 via second side surface 41. The ions of the p type impurity are implanted into source region 14 via first main surface 51. Second region 2 has: third region 3 formed to overlap with first region 1; and fourth region 4 formed to overlap with drift region 12, body region 13, and source region 14.

Five-stage implantation is performed in order to form the profile of the p type impurity concentration shown in FIG. 2, for example. First, aluminum is implanted into silicon carbide substrate 10 on conditions that an implantation dose amount is 3×10¹⁴ cm⁻² and implantation energy is 150 keV. Next, aluminum is implanted into silicon carbide substrate 10 on conditions that an implantation dose amount is 4×10¹⁴ cm⁻² and implantation energy is 300 keV. Next, aluminum is implanted into silicon carbide substrate 10 on the conditions that the implantation dose amount is 4×10¹⁴ cm⁻² and implantation energy is 500 keV. Next, aluminum is implanted into silicon carbide substrate 10 on conditions that an implantation dose amount is 4×10¹⁴ cm⁻² and implantation energy is 700 keV. Next, aluminum is implanted into silicon carbide substrate 10 on conditions that an implantation dose amount is 4×10¹⁴ cm⁻² and implantation energy is 900 keV. It should be noted that the order of implanting can be changed appropriately.

Four-stage implantation is performed in order to form the profile of the p type impurity concentration shown in FIG. 4, for example. First, aluminum is implanted into silicon carbide substrate 10 on conditions that an implantation dose amount is 3×10¹⁴ cm⁻² and implantation energy is 150 keV. Next, aluminum is implanted into silicon carbide substrate 10 on conditions that an implantation dose amount is 2×10¹⁴ cm⁻² and implantation energy is 300 keV. Next, aluminum is implanted into silicon carbide substrate 10 on conditions that an implantation dose amount is 8×10¹³ cm⁻² and implantation energy is 600 keV. Next, aluminum is implanted into silicon carbide substrate 10 on conditions that an implantation dose amount is 4×10¹³ cm⁻² and implantation energy is 1 MeV. It should be noted that the order of implanting can be changed appropriately.

One-stage implantation is performed in order to form the profile of the p type impurity concentration shown in FIG. 5, for example. Aluminum is implanted into silicon carbide substrate 10 on conditions that an implantation dose amount is 6×10¹⁴ cm⁻² and implantation energy is 100 keV. As described above, when the distance between first region 1 and second bottom surface 42 is short (for example, about 0.1 μm), second region 2 is formed by performing the ion implantation once. On the other hand, when the distance between first region 1 and second bottom surface 42 is long (for example, about 1 μm), second region 2 is formed by performing the ion implantation multiple times using different implantation energies. After the ion implantation step, mask 61 is removed.

Next, a step (S40: FIG. 10) of performing activation annealing is performed. Specifically, under an inert gas atmosphere, activation annealing is performed onto silicon carbide substrate 10. Accordingly, the ions of the impurities implanted in silicon carbide substrate 10 are activated. This activation annealing is preferably performed at a temperature of more than or equal to 1500° C. and less than or equal to 1900° C., for example, a temperature of approximately 1700° C. The activation annealing is performed for about 30 minutes, for example. An atmosphere for the activation annealing may be an Ar atmosphere, for example. Preferably, the step (S40: FIG. 10) of performing activation annealing is performed after the step (S30: FIG. 10) of forming the second region and before a step (850: FIG. 10) of forming the gate insulating film. In the step of performing activation annealing, it is desirable to heat silicon carbide substrate 10 with a protective film (not shown) being provided on silicon carbide substrate 10 to cover first main surface 51, first side surface 31, first bottom surface 32, second side surface 41, and second bottom surface 42. Accordingly, by the activation annealing, first main surface 51, first side surface 31, first bottom surface 32, second side surface 41, and second bottom surface 42 can be suppressed from being rough.

Next, the step (S50: FIG. 10) of forming the gate insulating film is performed. In an atmosphere including oxygen, silicon carbide substrate 10 is heated at a temperature of more than or equal to 1300° C. and less than or equal to 1400° C., for example. Accordingly, gate insulating film 15 is formed on silicon carbide substrate 10. Gate insulating film 15 is formed in contact with first main surface 51, gate trench 30, and source trench 40. Specifically, gate insulating film 15 is in contact with drift region 12 at first bottom surface 32, is in contact with drift region 12, body region 13, and source region 14 at first side surface 31, and is in contact with source region 14 at first main surface 51. Similarly, gate insulating film 15 is in contact with drift region 12 at first bottom surface 32, and is in contact with drift region 12, body region 13, and source region 14 at second side surface 41.

After forming gate insulating film 15 by thermally oxidizing silicon carbide substrate 10, heat treatment (NO annealing) may be performed onto silicon carbide substrate 10 in a nitrogen monoxide (NO) gas atmosphere. In the NO annealing, silicon carbide substrate 10 is held for about 1 hour on a condition of more than or equal to 1100° C. and less than or equal to 1300° C., for example. Accordingly, nitrogen atoms are introduced into an interface region between gate insulating film 15 and body region 13. As a result, formation of interface states in the interface region is suppressed, thereby achieving improved channel mobility. It should be rioted that a gas (for example, N₂O) other than the NO gas can be employed as the atmospheric gas as long as the nitrogen atoms can be introduced. After the NO annealing, Ar annealing may be further performed using argon (Ar) as an atmospheric gas. A heating temperature in the Ar annealing is more than or equal to the heating temperature of the above-described NO annealing, for example. The Ar annealing is performed for about 1 hour, for example. This further suppresses formation of an interface state at the interface region between gate insulating film 15 and body region 13.

Next, a step of forming the gate electrode is performed. For example, by a LPCVD (Low Pressure Chemical Vapor Deposition) method, gate electrode 27 is formed on gate insulating film 15. The gate electrode is composed of polysilicon, for example. Gate electrode 27 is disposed inside gate trench 30, and is formed to face each of first side surface 31 and first bottom surface 32 of gate trench 30 on gate insulating film 15. Similarly, gate electrode 27 is disposed inside source trench 40, and is formed to face each of second side surface 41 and second bottom surface 42 of source trench 40 on gate insulating film 15 (see FIG. 17). Next, a portion of gate electrode 27 in source trench 40 is removed by etching.

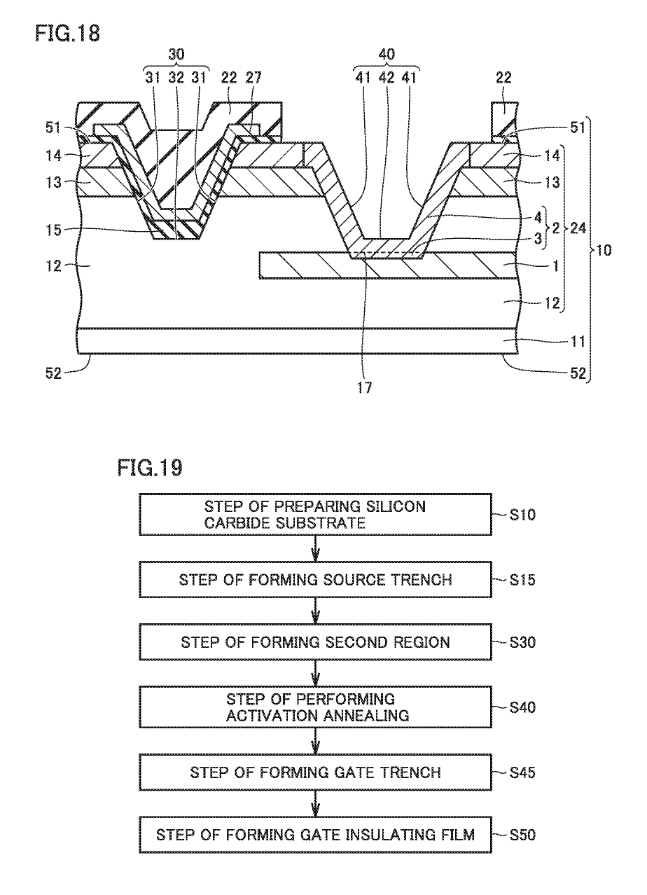

Next, a step of forming the interlayer insulating film is formed. For example, interlayer insulating film 22 is formed in contact with gate insulating film 15 so as to cover gate electrode 27. Preferably, interlayer insulating film 22 is formed by chemical vapor deposition, for example. Interlayer insulating film 22 is composed of a material including silicon dioxide, for example. Next, interlayer insulating film 22 and a portion of gate insulating film 15 are etched. Accordingly, source trench 40 is exposed from gate insulating film 15 (see FIG. 18).

Next, a step of forming the source electrode is performed. For example, a sputtering method is employed to form source electrode 16 in contact with both source region 14 and second region 2. Source electrode 16 is formed in source trench 40, Specifically, source electrode 16 is in contact with second region 2 at second side surface 41, second bottom surface 42, and first main surface 51. Source electrode 16 is in contact with source region 14 at first main surface 51. Source electrode 16 is composed of a material including TiAlSi, for example. Next, alloying annealing is performed. Specifically, source electrode 16 in contact with source region 14 and second region 2 is held for about 5 minutes at a temperature of more than or equal to 900° C. and less than or equal to 1100° C., for example. Accordingly, at least a portion of source electrode 16 reacts with silicon included in silicon carbide substrate 10 and is accordingly silicided. Accordingly, source electrode 16 in ohmic junction with source region 14 is formed. Preferably, source electrode 16 is in ohmic junction with second region 2.

Next, source interconnection 19 electrically connected to source electrode 16 is formed. Source interconnection 19 is formed in contact with source electrode 16 in source trench 40. Next, in second main surface 52, back grinding is performed to silicon carbide substrate 10. Accordingly, silicon carbide substrate 10 is thinned. Next, drain electrode 20 is formed in contact with second main surface 52. In the manner described above, MOSFET 100 (FIG. 1) according to the present embodiment s manufactured.

In the above-described embodiment, it has been described that the first conductivity type and the second conductivity type respectively correspond to the n type and the p type; however, the first conductivity type and the second conductivity type may respectively correspond to the p type and the n type. Moreover, in the above-described embodiment, it has been described that the silicon carbide semiconductor device is a MOSFET; however, the silicon carbide semiconductor device is not limited to a MOSFET The silicon carbide semiconductor device may be an IGBT (Insulated Gate Bipolar Transistor) or the like, for example.

### (First Modification of Method for Manufacturing Silicon Carbide Semiconductor Device)

Next, the following describes a first modification of the method for manufacturing MOSFET 100. The method for manufacturing the MOSFET according to the first modification is different from the above-described method for manufacturing MOSFET 100 according to the present embodiment in that the step of forming the gate trench and the step of forming the source trench are performed separately, and is substantially the same as the above-described method for manufacturing MOSFET 100 according to the present embodiment in the other points. The following mainly describes the difference from the above-described method for manufacturing MOSFET 100 according to the present embodiment.

First, a step (S10: FIG. 19) of preparing a silicon carbide substrate is performed. Specifically, as a result of the steps shown in FIG. 11 to FIG. 13, silicon carbide substrate 10 including drift region 12, first region 1, body region 13, and source region 14 is prepared.

Next, a step (S15: FIG. 19) of forming the source trench is performed. For example, mask 60 provided with an opening above a location in which source trench 40 (FIG. 1) is to be formed is formed on first main surface 51 constituted of source region 14. Using mask 60, etching is performed to remove source region 14, body region 13, and a portion of drift region 12. An exemplary, usable etching method is reactive ion etching, in particular, inductively coupled plasma reactive ion etching. Specifically, for example, inductively coupled plasma reactive ion etching can be used in which SF₆ or a mixed gas of SF₆ and O₂ is used as reactive gas. By the etching, a recess is formed in the region in which source trench 40 is to be formed. The recess includes: a side portion substantially perpendicular to first main surface 51; and a bottom portion provided to be continuous to the side portion and substantially parallel to first main surface 51.

Next, thermal etching is performed in the recess. For example, in the state in which mask 60 is formed on first main surface 51, the thermal etching can be performed by performing heating in an atmosphere including reactive gas having at least one or more types of halogen atoms. The at least one or more types of halogen atoms include at least one of chlorine (Cl) atom and fluorine (F) atom. This atmosphere includes Cl₂, BCl₃, SF₆, or CR₄, for example. For example, the thermal etching is performed using a mixed gas of chlorine gas and oxygen gas as a reactive gas, at a heat treatment temperature of, for example, more than or equal to 700° C. and less than or equal to 1000° C. It should be noted that the reactive gas may contain a carrier gas in addition to the chlorine gas and the oxygen gas. An exemplary, usable carrier gas is nitrogen gas, argon gas, helium gas, or the like.

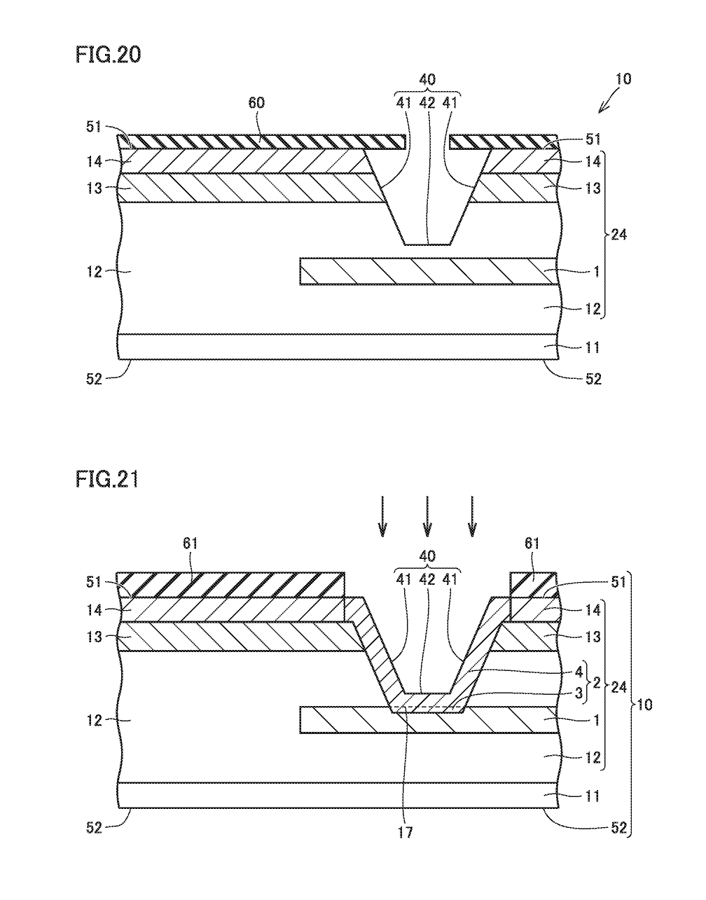

By the thermal etching, source trench 40 is formed in first main surface 51 (see FIG. 20). Source trench 40 is defined by: second side surface 41 continuous to first main surface 51; and second bottom surface 42 continuous to second side surface 41. Second side surface 41 is constituted of source region 14, body region 13, and drift region 12. Second bottom surface 42 is constituted of drift region 12. Angle θ2 of second side surface 41 relative to second bottom surface 42 is 54.7°, for example. Next, mask 60 is removed from first main surface 51.

Next, a step (S30: FIG. 19) of forming the second region is performed. First, a mask 61 provided with an opening above a region in which the second region is to be formed is formed (see FIG. 21). Mask 61 is formed to cover first main surface 51. Next, an ion implantation step is performed. Using mask 61, ions of a p type impurity such as aluminum are implanted into second side surface 41 and second bottom surface 42 of source trench 40, for example. Accordingly, second region 2 having the p type is formed in contact with first region 1. The ion implantation of the p type impurity is performed in a direction substantially perpendicular to first main surface 51 (direction of arrow in FIG. 21). The ions of the p type impurity are implanted into drift region 12 and first region 1 via second bottom surface 42. The ions of the p type impurity are implanted into source region 14, body region 13, and drill region 12 via second side surface 41. The ions of the p type impurity are implanted into source region 14 via first main surface 51. Second region 2 has: third region 3 formed to overlap with first region 1; and fourth region 4 formed to overlap with drift region 12, body region 13, and source region 14. Next, mask 61 is removed.

Next, a step (S40: FIG. 19) of performing activation annealing is performed. Specifically, under an inert gas atmosphere, activation annealing is performed onto silicon carbide substrate 10. Accordingly, the ions of the impurities implanted in silicon carbide substrate 10 are activated. This activation annealing is preferably performed at a temperature of more than or equal to 1500° C. and less than or equal to 1900° C., for example, a temperature of approximately 1700° C. The activation annealing is performed for about 30 minutes, for example. The atmosphere of the activation annealing is an Ar atmosphere, for example. Preferably, the activation annealing is performed onto silicon carbide substrate 10 with first main surface 51 being covered with the protective film.

Next, a step (S45: FIG. 19) of forming the gate trench is performed. For example, a mask 62 provided with an opening above a location in which gate trench 30 (FIG. 1) are to be formed is formed on first main surface 51 constituted of source region 14. Mask 62 is formed to cover source trench 40. Using mask 62, etching is performed to remove source region 14, body region 13, and a portion of drift region 12. An exemplary, usable etching method is reactive ion etching, in particular, inductively coupled plasma reactive ion etching. Specifically, for example, inductively coupled plasma reactive ion etching can be used in which SF₆ or a mixed gas of SF₆ and O₂ is used as reactive gas. By the etching, a recess is formed in the region in which gate trench 30 is to be formed. The recess includes: a side portion substantially perpendicular to first main surface 51; and a bottom portion provided to be continuous to the side portion and substantially parallel to first main surface 51.

Next, thermal etching is performed in the recess. For example, in the state in which mask 62 is formed on first main surface 51, the thermal etching can be performed by performing heating in an atmosphere including reactive gas having at least one or more types of halogen atoms. The at least one or more types of halogen atoms include at least one of chlorine (Cl) atom and fluorine (F) atom. The atmosphere includes Cl₂, BCl₃, SF₆, or CF₄, for example. For example, the thermal etching is performed using a mixed gas of chlorine gas and oxygen gas as a reactive gas, at a heat treatment temperature of, for example, more than or equal to 700° C. and less than or equal to 1000° C. It should be noted that the reactive gas may contain a carrier gas in addition to the chlorine gas and the oxygen gas. As the carrier gas, nitrogen gas, argon gas, or helium gas can be used, for example.

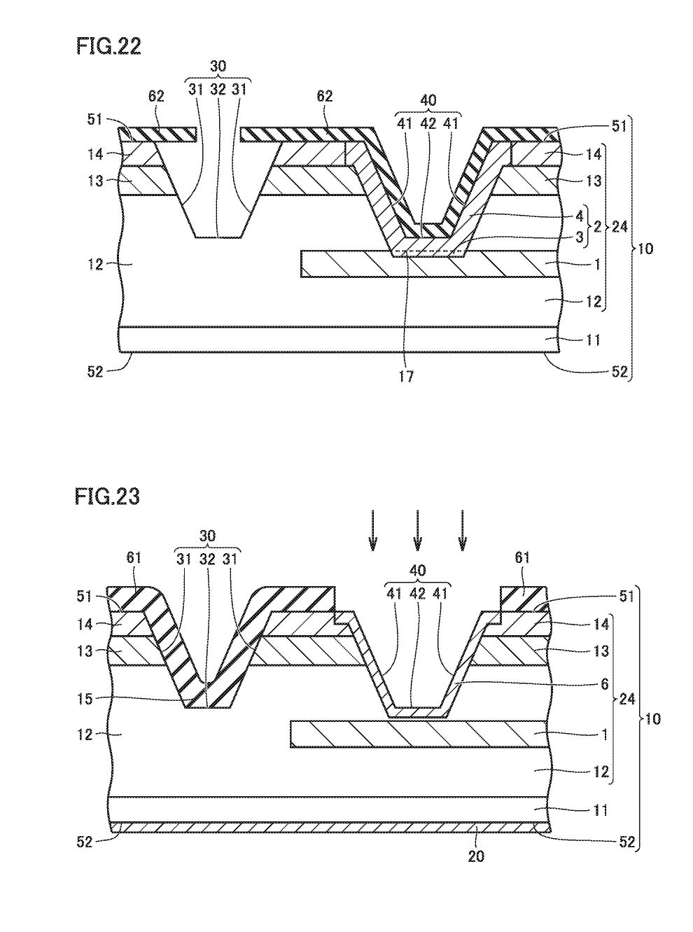

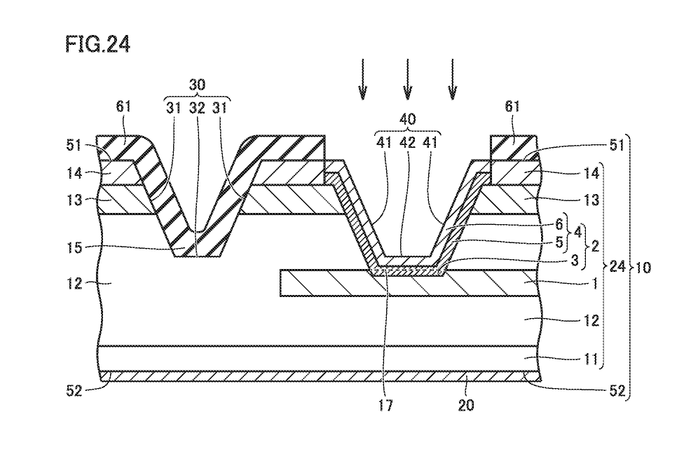

By the thermal etching, gate trench 30 is formed in first main surface 51. (see FIG. 22). Gate trench 30 is defined by: first side surface 31 continuous to first main surface 51; and first bottom surface 32 continuous to first side surface 31. First side surface 31 is constituted of source region 14, body region 13, and drift region 12.

First bottom surface 32 is constituted of drift region 12. Angle θ1 of first side surface 31 relative to first bottom surface 32 is 54.7°, for example. Next, mask 62 is removed from first main surface 51.

Next, a step (S50: FIG. 19) of forming the gate insulating film is performed. In an atmosphere including oxygen, silicon carbide substrate 10 is heated at a temperature of more than or equal to 1300° C. and less than or equal to 1400° C., for example. Accordingly, gate insulating film 15 is formed on silicon carbide substrate 10. Next, gate electrode 27 is formed on Rate insulating film 15 (see FIG. 17). Next, interlayer insulating film 22 is formed on gate electrode 27. Next, gate insulating film 15 on source trench 40 is removed by etching (see FIG. 18). Next, source electrode 16 and source interconnection 19 are formed in source trench 40. Next, drain electrode 20 is formed on second main surface 52. In the manner described above, MOSFET 100 shown in FIG. 1 is manufactured.

### (Second Modification of Method for Manufacturing Silicon Carbide Semiconductor Device)

Next, the following describes a second modification of the method for manufacturing MOSFET 100. The method for manufacturing the MOSFET according to the second modification is different from the above-described method for manufacturing MOSFET 100 according to the present embodiment mainly in that the p type impurity concentration profile is formed in separate two stages by two-stage implantation, and is substantially the same as the above-described method for manufacturing MOSFET 100 according to the present embodiment in the other points. The following mainly describes the difference from the above-described method for manufacturing MOSFET 100 according to the present embodiment.

In the method for manufacturing the MOSFET according to the second modification, the second region is formed to have the p type impurity concentration profile shown in FIG. 8. The step of forming the second region includes: a first step of performing ion implantation on a condition of first energy and a first dose amount; and a second step of performing ion implantation on a condition of second energy and a second dose amount.

As shown in FIG. 23, in the first step, ions of the p type impurity are implanted into silicon carbide substrate 10 on a condition of the first energy and the first dose amount. The first energy is 150 keV, for example. The first dose amount is 6×10¹⁴ cm⁻². The first energy may be more than or equal to 10 keV and less than or equal to 600 keV. The first dose amount may be more than or equal to 1×10¹⁴ cm⁻² and less than or equal to 1×10¹⁶ cm⁻², for example. Accordingly, sixth region 6 constituting both second side surface 41 and second bottom surface 42 is formed. Sixth region 6 may constitute a portion of first main surface 51. Sixth region 6 is in contact with source region 14, body region 13, and drift region 12. Sixth region 6 is separated from first region 1. Drift region 12 is located between first region 1 and sixth region 6.

Next, the second step is performed. In the second step, ions of the p type impurity are implanted into silicon carbide substrate 10 on a condition of the second energy and the second dose amount. The second energy in the second step is higher than the first energy in the first step. Accordingly, in the second step, the ions of the p type impurity are implanted into a location deeper than that in the first step. The second energy is 600 keV, for example. The second energy may be more than or equal to 600 keV and less than or equal to 1 MeV. Accordingly, third region 3 overlapping with first region 1, and fifth region 5 in contact with drift region 12 are formed. Fifth region 5 is continuous to both third region 3 and fourth region 4. The second dose amount is lower than the first dose amount. Accordingly, arm ion implantation time in the second step is shorter than an ion implantation time in the first step. The second dose amount is 3×10¹⁴ cm⁻², for example. The second dose amount may be more than or equal to 1×10¹³ cm^{31 2} and less than or equal to 1×10¹⁵ cm⁻². By achieving a low concentration of the p type impurity in each of fifth region 5 and third region 3 not contributing to reduction of contact resistance with source electrode 16 while maintaining a high concentration of the p type impurity in sixth region 6 contributing to reduction of contact resistance with source electrode 16, a time required to form the entire second region 2 can be shortened. In the description above, it has been described that the second step is performed after the first step; however, the second step may be performed first and the first step may be performed after the second step.

The embodiments disclosed herein are illustrative and non-restrictive in any respect. The scope of the present invention is defined by the terms of the claims, rather than the embodiments described above, and is intended to include any modifications within the scope and meaning equivalent to the terms of the claims.

### REFERENCE SIGNS LIST

1: first region; 2: second region; 3: third region; 4: fourth region; 5: fifth region; 6: sixth region; 7: seventh region; 8: eighth region; 9: ninth region; 10: silicon carbide substrate; 11: silicon carbide single crystal substrate; 12: drift region; 13: body region; 14: source region; 15: gate insulating film; 16: source electrode; 17: boundary; 18: impurity region; 19: source interconnection; 20: drain electrode; 22: interlayer insulating film; 24: silicon carbide epitaxial layer; 27: gate electrode; 30: gate trench; 31: first side surface; 32: first bottom surface; 40: source trench; 41: second side surface; 42: second bottom surface; 43: first side portion; 44: second side portion; 51: first main surface; 52: second main surface; 53: surface; 60, 61, 62: mask; 100: MOSFET (silicon carbide semiconductor device).

1. A silicon carbide semiconductor device comprising:
a silicon carbide substrate having a first main surface and a second main surface opposite to the first main surface;
a gate insulating film; and
a source electrode, wherein
a gate trench and a source trench are provided in the first main surface,
the gate trench is defined by a first side surface continuous to the first main surface and a first bottom surface continuous to the first side surface,
the source trench is defined by a second side surface continuous to the first main surface and a second bottom surface continuous to the second side surface,
the silicon carbide substrate includes
a drift region having a first conductivity type,
a body region provided on the drift region and having a second conductivity type different from the first conductivity type,
a source region on the body region, the source region being separated from the drift region by the body region, the source region having the first conductivity type,
a first region between the second bottom surface and the second main surface, the first region having the second conductivity type, and
a second region in contact with the first region, the second region constituting at least a portion of the second side surface and the second bottom surface, the second region having the second conductivity type,
the gate insulating film is in contact with the drift region, the body region, and the source region at the first side surface, and the gate insulating film is in contact with the drift region at the first bottom surface, and
the source electrode is in contact with the second region at the second side surface and the second bottom surface.

2. The silicon carbide semiconductor device according to claim 1, wherein
the second region constitutes a portion of the first main surface, and
the source electrode is in contact with the second region at the first main surface.

3. The silicon carbide semiconductor device according to claim 2, wherein
the second region has a third region and a fourth region, the third region being in contact with the first region, the fourth region being continuous to the third region, the fourth region being in contact with the drift region, and
a concentration of a second conductivity type impurity in the second bottom surface is higher than a concentration of the second conductivity type impurity in a boundary between the third region and the fourth region.

4. The silicon carbide semiconductor device according to claim 2, wherein an angle of the first side surface relative to the first bottom surface is more than or equal to 50° and less than or equal to 65°.

5. The silicon carbide semiconductor device according to claim 2, wherein an angle of the second side surface relative to the second bottom surface is more than or equal to 50° and less than or equal to 65°.

6. The silicon carbide semiconductor device according to claim 2, wherein an angle of the second side surface relative to the second bottom surface is more than 65° and less than or equal to 90°.

7. The silicon carbide semiconductor device according to claim 6, wherein in a direction perpendicular to the second main surface, the second bottom surface is located between the source region and the drift region.

8. The silicon carbide semiconductor device according to claim 6, wherein in a direction perpendicular to the second main surface, the second bottom surface is located between the body region and the first region.

9. The silicon carbide semiconductor device according to claim 2, wherein
the silicon carbide substrate further includes an impurity region, the impurity region having the first conductivity type, the impurity region being located between the first bottom surface and the second main surface, the impurity region facing the first region, and
a concentration of a first conductivity type impurity in the impurity region is higher than a concentration of the first conductivity type impurity in the drift region.

10. The silicon carbide semiconductor device according to claim 2, wherein
the second side surface has a first side portion continuous to the second bottom surface, and a second side portion continuous to the first side portion, and
an angle of the first side portion relative to the second bottom surface is smaller than an angle of the second side portion relative to a plane parallel to the second bottom surface.

11. The silicon carbide semiconductor device according to claim 1, wherein
the source electrode is in contact with the source region at the second side surface, and
the second region is separated from the first main surface.

12. The silicon carbide semiconductor device according to claim 11, wherein
the second region has a third region and a fourth region, the third region being in contact with the first region, the fourth region being continuous to the third region, the fourth region being in contact with the drift region, and
a concentration of a second conductivity type impurity in the second bottom surface is higher than a concentration of the second conductivity type impurity in a boundary between the third region and the fourth region.

13. The silicon carbide semiconductor device according to claim 11, wherein an angle of the first side surface relative to the first bottom surface is more than or equal to 50° and less than or equal to 65°.

14. The silicon carbide semiconductor device according to claim 11, wherein an angle of the second side surface relative to the second bottom surface is more than or equal to 50° and less than or equal to 65°.

15. The silicon carbide semiconductor device according to claim 11, wherein an angle of the second side surface relative to the second bottom surface is more than 65° and less than or equal to 90°.

16. The silicon carbide semiconductor device according to claim 15, wherein in a direction perpendicular to the second main surface, the second bottom surface is located between the source region and the drift region.

17. The silicon carbide semiconductor device according to claim 15, wherein in a direction perpendicular to the second main surface, the second bottom surface is located between the body region and the first region.

18. The silicon carbide semiconductor device according to claim 11, wherein
the silicon carbide substrate further includes an impurity region, the impurity region having the first conductivity type, the impurity region being located between the first bottom surface and the second main surface, the impurity region facing the first region, and
a concentration of a first conductivity type impurity in the impurity region is higher than a concentration of the first conductivity type impurity in the drift region.

19. The silicon carbide semiconductor device according to claim 11, wherein
the second side surface has a first side portion continuous to the second bottom surface, and a second side portion continuous to the first side portion, and
an angle of the first side portion relative to the second bottom surface is smaller than an angle of the second side portion relative to a plane parallel to the second bottom surface.

20. The silicon carbide semiconductor device according to claim 1, wherein the first main surface corresponds to a {0001} plane or a plane angled off by less than or equal to 8° relative to the {0001} plane.

21. A silicon carbide semiconductor device comprising:
a silicon carbide substrate having a first main surface and a second main surface opposite to the first main surface;
a gate insulating film; and
a source electrode, wherein
the first main surface corresponds to a {0001} plane or a plane angled off by less than or equal to 8° relative to the {0001} plane,
a gate trench and a source trench are provided in the first main surface,
the gate trench is defined by a first side surface continuous to the first main surface and a first bottom surface continuous to the first side surface, and an angle of the first side surface relative to the first bottom surface is more than or equal to 50° and less than or equal to 65°,
the source trench is defined by a second side surface continuous to the first main surface and a second bottom surface continuous to the second side surface, and an angle of the second side surface relative to the second bottom surface is more than or equal to 50° and less than or equal to 65°,
the silicon carbide substrate includes
a drift region having a first conductivity type,
a body region provided on the drift region and having a second conductivity type different from the first conductivity type,
a source region on the body region, the source region being separated from the drift region by the body region, the source region having the first conductivity type,
a first region between the second bottom surface and the second main surface, the first region having the second conductivity type, and
a second region in contact with the first region, the second region constituting at least a portion of the second side surface and the second bottom surface, the second region having the second conductivity type,
the gate insulating film is in contact with the drift region, the body region, and the source region at the first side surface, and the gate insulating film is in contact with the drift region at the first bottom surface,
the source electrode is in contact with the second region at the second side surface and the second bottom surface,
the second region has a third region and a fourth region, the third region being in contact with the first region, the fourth region being continuous to the third region, the fourth region being in contact with the drift region, and
a concentration of a second conductivity type impurity in the second bottom surface is higher than a concentration of the second conductivity type impurity in a boundary between the third region and the fourth region.

22.-26. (canceled)

27. A method for manufacturing a silicon carbide semiconductor device, the method comprising:
preparing a silicon carbide substrate having a first main surface and a second main surface opposite to the first main surface; and
forming a gate trench and a source trench simultaneously in the first main surface by thermal etching, wherein
the gate trench is defined by a first side surface continuous to the first main surface and a first bottom surface continuous to the first side surface,
the source trench is defined by a second side surface continuous to the first main surface and a second bottom surface continuous to the second side surface,
the silicon carbide substrate includes
a drift region having a first conductivity type,
a body region provided on the drift region and having a second conductivity type different from the first conductivity type,
a source region on the body region, the source region being separated from the drift region by the body region, the source region having the first conductivity type, and
a first region between the second bottom surface and the second main surface, the first region having the second conductivity type,
the method further comprising:
forming a second region by performing ion implantation to the second side surface and the second bottom surface, the second region being in contact with the first region, the second region constituting at least a portion of the second side surface and the second bottom surface, the second region having the second conductivity type;
performing activation annealing to the silicon carbide substrate after the forming of the second region;
forming a gate insulating film after the performing of the activation annealing to the silicon carbide substrate, the gate insulating film being in contact with the drift region, the body region, and the source region at the first side surface, the gate insulating film being in contact with the drift region at the first bottom surface; and
forming a source electrode in contact with the second region at the second side surface and the second bottom surface, wherein
the forming of the second region includes
performing ion implantation on a condition of first energy and a first dose amount, and
performing ion implantation on a condition of second energy and a second dose amount, the second energy being higher than the first energy, the second dose amount being lower than the first dose amount.
